(19) United States
(12) Patent Application Publication
(10) Pub. No.: US 2024/0242766 A1
(43) Pub. Date: Jul. 18, 2024

(54) MEMORY DEVICE AND MEMORY DEVICE OPERATING METHOD

(71) Applicant: Samsung Electronics Co., Ltd., Suwon-si (KR)

(72) Inventor: Hyun Seo, Suwon-si (KR)

(21) Appl. No.: 18/485,353

(22) Filed: Oct. 12, 2023

(30) Foreign Application Priority Data
Jan. 18, 2023 (KR) 10-2023-0007350
Apr. 5, 2023 (KR) 10-2023-0044736

(51) Int. Cl. G11C 16/10; G11C 16/08; G11C 16/28

(52) U.S. Cl. CPC G11C 16/102; G11C 16/08; G11C 16/28

(57) ABSTRACT

A memory device includes a memory cell that is configured to have data stored therein, and a control logic that is configured to determine a dummy voltage based on a location of a selected word line electrically connected to the memory cell, and is configured to apply the dummy voltage to dummy word lines. First and second ones of the dummy word lines are adjacent to opposing ends in a vertical direction of a memory NAND string including the memory cell, respectively.

### CROSS-REFERENCE TO RELATED APPLICATION(S)

This application claims priority to and the benefit of Korean Patent Application No. 10-2023-0044736 filed in the Korean Intellectual Property Office on Apr. 5, 2023, and priority to and the benefit of Korean Patent Application No. 10-2023-0007350 filed in the Korean Intellectual Property Office on Jan. 18, 2023, the entire contents of which are incorporated herein by reference.

### BACKGROUND

### (a) Field

The present disclosure relates to a memory device and a memory device operating method.

### (b) Description of the Related Art

Non-volatile memory devices include read-only memory (ROM), programmable ROM (PROM), electrically programmable ROM (EPROM), electrically erasable and programmable ROM (EEPROM), flash memory, phase-change random access memory (PRAM), magnetic RAM (MRAM), resistive RAM (RRAM), ferroelectric RAM (FRAM), etc.

Non-volatile memory devices may be implemented in various forms such as solid state drives (SSDs), memory cards, etc. Non-volatile memory devices have been used in various computing devices such as computers, smart phones, smart pad tablets, wearable devices, etc., to store data.

With the development of semiconductor manufacturing technology, the degrees of integration of non-volatile memory devices have been continuously raised, and accordingly, the capacities thereof have been continuously increased. Raising the degrees of integration of non-volatile memory devices has the advantage of reducing the production cost of the non-volatile memory devices. However, while the scales of non-volatile memory devices have been decreased and the structures thereof have been changed as the degrees of integration of the non-volatile memory devices have been raised, various problems that had not been previously found have been discovered.

One of various problems that have been discovered is that the reliability of non-volatile memory devices can decrease due to a feature of a process. For this reason, new technologies for preventing reliability from decreasing due to a feature of a process have been needed.

### SUMMARY

Example embodiments attempt to provide a memory device with improved reliability.

A memory device according to some embodiments includes a memory cell that is configured to have data stored therein, and a control logic that is configured to determine a dummy voltage based on a location of a selected word line electrically connected to the memory cell, and is configured to apply the dummy voltage to dummy word lines. First and second ones of the dummy word lines may be adjacent to opposing ends in a vertical direction of a memory NAND string including the memory cell, respectively.

The memory NAND string may be on a substrate and include a multi-stack structure that includes a first stack and a second stack on the first stack, the first stack may be between the second stack and the substrate, and third and fourth ones of the dummy word lines may be adjacent to a junction between the first stack and the second stack.

The control logic may be configured to determine the dummy voltage based on the location of the selected word line in one of the first and second stacks.

The control logic may be configured to determine the dummy voltage based on which one of the first and second stacks the selected word line is located in.

In a case of Top-to-Bottom (T2B) programming, the control logic may be configured to apply the dummy voltage having a first voltage when the selected word line is located in the first stack, and may be configured to apply the dummy voltage having a second voltage lower than the first voltage when the selected word line is located in the second stack.

In a case of Bottom-to-Top (B2T) programming, the control logic may be configured to apply the dummy voltage having a first voltage when the selected word line is located in the first stack, and may be configured to apply the dummy voltage having a second voltage higher than the first voltage when the selected word line is located in the second stack.

The memory NAND string may be on a substrate, and, when the location of the selected word line is higher than a first height in the memory NAND string relative to the substrate, the control logic may be configured to apply the dummy voltage having a lower voltage than a voltage applied by the control logic when the location of the selected word line is lower than the first height in the memory NAND string, in a case of Top-to-Bottom (T2B) programming.

The control logic may be configured to determine a first reference point in the memory NAND string and a second reference point higher than the first reference point in the memory NAND string relative to the substrate, determine the selected word line is a lower word line when the location of the selected word line is lower than the first reference point, determine the selected word line is a middle word line when the location of the selected word line is between the first reference point and the second reference point, and determine the selected word line is an upper word line when the location of the selected word line is higher than the second reference point, and apply the dummy voltage having a first voltage when the selected word line is the lower word line, apply the dummy voltage having a second voltage lower than the first voltage when the selected word line is the middle word line, and apply the dummy voltage having a third voltage lower than the second voltage when the selected word line is the upper word line.

The memory NAND string may be on a substrate, and, when the location of the selected word line is lower than a first height in the memory NAND string relative to the substrate, the control logic may be configured to apply the dummy voltage having a lower voltage than a voltage applied by the control logic when the location of the selected word line is higher than the first height in the memory NAND string, in a case of Bottom-to-Top (B2T) programming.

The control logic may be configured to determine a first reference point in the memory NAND string and a second reference point higher than the first reference point in the memory NAND string relative to the substrate, determine the selected word line is a lower word line when the location of the selected word line is lower than the first reference point, determine the selected word line is a middle word line when the location of the selected word line is between the first reference point and the second reference point, and determine the selected word line is an upper word line when the location of the selected word line is higher than the second reference point, and apply the dummy voltage having a first voltage when the selected word line is the lower word line, apply the dummy voltage having a second voltage higher than the first voltage when the selected word line is the middle word line, and apply the dummy voltage having a third voltage higher than the second voltage when the selected word line is the upper word line.

The control logic may be configured to determine the dummy voltage based on a program/erase cycle (P/E cycle) or a temperature of the memory cell.

The control logic may be configured to apply the dummy voltage having a first voltage when the P/E cycle of the memory cell is higher than a first reference value, and may be configured to apply the dummy voltage having a second voltage lower than the first voltage when the P/E cycle of the memory cell is lower than the first reference value.

The control logic may be configured to apply the dummy voltage having a first voltage when the temperature of the memory cell is higher than a first reference value, and may be configured to apply the dummy voltage having a second voltage higher than the first voltage when the temperature of the memory cell is lower than the first reference value.

A memory device according to some embodiments may include a memory cell that is configured to have data stored therein, and a control logic that is configured to apply a verification voltage to a selected word line electrically connected to the memory cell during a verifying period for verifying the memory cell, apply a dummy voltage to dummy word lines during the verifying period, and apply a verification pass voltage to unselected word lines other than the dummy word lines during the verifying period.

The control logic may be configured to apply the dummy voltage in a word line setup section of the verifying period.

The control logic may be configured to apply the dummy voltage in a bit line setup section of the verifying period.

The verifying period may include a first state verification section for verifying a first state of the memory cell, and, in a second state verification section following the first state verification section, the control logic may be configured to lower the dummy voltage while lowering the verification voltage in order to verify a second state of the memory cell.

A memory device operating method according to some embodiments may include applying a verification voltage to a selected word line electrically connected to a memory cell having data stored therein, determining a dummy voltage based on a location of the selected word line, and applying the dummy voltage to dummy word lines located at an upper end and a lower end of a memory NAND string including the memory cell, respectively.

The memory NAND string may be on a substrate, and determining the dummy voltage may include determining the dummy voltage as a first voltage when the location of the selected word line is higher than a first height in the memory NAND string relative to the substrate and determining the dummy voltage as a second voltage higher than the first voltage when the location of the selected word line is lower than the first height in the memory NAND string, in a case where the data has been programmed by Top-to-Bottom (T2B) programming, and determining the dummy voltage as a third voltage when the location of the selected word line is higher than the first height in the memory NAND string and determining the dummy voltage as a fourth voltage lower than the third voltage when the location of the selected word line is lower than the first height in the memory NAND string, in a case where the data has been programmed by Bottom-to-Top (B2T) programming.

Applying the dummy voltage may include applying the dummy voltage in a word line setup section or a bit line setup section following the word line setup section.

### BRIEF DESCRIPTION OF THE DRAWINGS

FIG. 1 is a schematic block diagram of a memory system according to some embodiments.

FIG. 2 is a schematic block diagram for explaining the memory device shown in FIG. 1.

FIG. 3 is a schematic diagram for explaining a memory cell array according to some embodiments.

FIG. 4 is a perspective cross-sectional view for explaining one memory block of the memory cell array according to some embodiments.

FIG. 5 is an electric equivalent circuit diagram of a part of the memory block of FIG. 4.

FIG. 6 is a view for explaining a memory NAND string of a multi-stack structure according to some embodiments.

FIG. 7 is an electric equivalent circuit diagram of the memory NAND string of FIG. 6.

FIG. 8 is graphs for explaining cell distribution change during the operation of the memory device according to some embodiments.

FIG. 9 is graphs for explaining a change in dummy voltage which is applied by a memory device according to some embodiments.

FIG. 10 is a drawing for explaining a configuration in which the memory device according to some embodiments applies dummy voltage.

FIG. 11 is a drawing for explaining a configuration in which the memory device according to some embodiments applies dummy voltage.

FIG. 12 is a drawing for explaining a configuration in which the memory device according to some embodiments applies dummy voltage.

FIG. 13 is a drawing for explaining a configuration in which the memory device according to some embodiments applies dummy voltage.

FIG. 14 is a drawing for explaining a configuration in which the memory device according to some embodiments applies dummy voltage.

FIG. 15 is a drawing for explaining a configuration in which the memory device according to some embodiments applies dummy voltage.

FIG. 16 is a drawing for explaining a configuration in which the memory device according to some embodiments applies dummy voltage.

FIG. 17 is a drawing for explaining a configuration in which the memory device according to some embodiments applies dummy voltage.

FIG. 18 is a drawing for explaining a configuration in which the memory device according to some embodiments applies dummy voltage.

FIG. 19 is a drawing for explaining a configuration in which the memory device according to some embodiments applies dummy voltage.

FIG. 20 is a flow chart of a memory device operating method according to some embodiments.

FIG. 21 is a drawing illustrating a memory device according to some embodiments.

FIG. 22 is a schematic block diagram of a computing system according to some embodiments.

### DETAILED DESCRIPTION OF THE EMBODIMENTS

In the following detailed description, only certain example embodiments have been shown and described, simply by way of illustration. As those skilled in the art would realize, the described embodiments may be modified in various different ways, all without departing from the scope of the present disclosure.

Accordingly, the drawings and description are to be regarded as illustrative in nature and not restrictive. Like reference numerals designate like elements throughout the specification. In the flow charts described with reference to the drawings, the order of operations may be changed, and several operations may be combined, and an operation may be divided, and some operations may not be performed.

Further, expressions written in the singular forms can be comprehended as the singular forms or plural forms unless clear expressions such as “a”, “an”, or “single” are used. Terms including an ordinal number, such as first and second, are used for describing various constituent elements, but the constituent elements are not limited by the terms. The terms are used only to discriminate one constituent element from other constituent elements.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

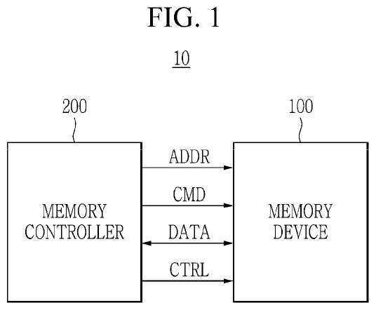

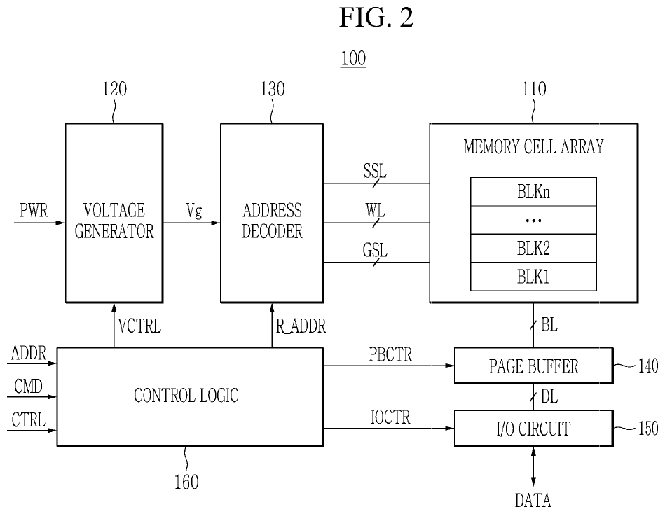

FIG. 1 is a schematic block diagram of a memory system according to some embodiments, and FIG. 2 is a schematic block diagram for explaining the memory device shown in FIG. 1.

Referring to FIG. 1, a memory system 10 may perform communication with a host through various interfaces. The host may request a data processing operation of the memory system 10, such as a data read operation, a data writing (programming) operation, a data erasing operation, etc. For example, the host may be a central processing unit (CPU), graphic processing unit (GPU), a microprocessor, an application processor (AP), etc.

In some embodiments, the memory system 10 may be included in a storage device. For example, the storage device may be implemented in various types, such as a solid-state drive (SSD), an embedded multimedia card (eMMC), universal flash storage (UFS), compact flash (CF), secure digital (SD), micro secure digital (Micro-SD), mini secure digital (Mini_SD), extreme digital (xD), a memory stick, etc.

The memory system 10 may include a memory device 100 and a memory controller 200.

The memory controller 200 may be configured to access the memory device 100 in response to a request from the host. The memory controller 200 may be configured to provide an interface between the memory device 100 and the host. Also, the memory controller 200 may be configured to drive firmware for controlling the memory device 100.

The memory controller 200 may control the operation of the memory device 100. Specifically, the memory controller 200 may provide at least one of an address (ADDR), a command (CMD), data (DATA), or a control signal (CTRL), along an input/output line connected to the memory device 100.

The memory controller 200 may use at least one of an address (ADDR), a command (CMD), or a control signal (CTRL) to write data in the memory device 100, erase data from the memory device 100, or read data from the memory device 100. A control signal (CTRL) may include a chip-enable (CE) signal, a write-enable (WE) signal, a read-enable (RE) signal, etc.

The memory device 100 may operate under the control of the memory controller 200. The memory device 100 may be a non-volatile memory device such as a NAND flash memory, a vertical NAND (VNAND) flash memory, a bonding vertical NAND (BVNAND) flash memory, a NOR flash memory, a resistive random access memory (RRAM), a phase-change RAM (PRAM), a magneto resistive RAM (MRAM), a ferroelectric RAM (FRAM), a spin transfer torque RAM (STT-RAM), a conductive bridging RAM (CBRAM), etc.

Referring to FIG. 2, the memory device 100 may include a memory cell array 110, a voltage generator 120, an address decoder 130, a page buffer 140, an input/output (I/O) circuit 150, and a control logic 160 (also referred to as a control logic circuit).

The memory cell array 110 may include a plurality of memory blocks BLK1 to BLKn. Each of the plurality of memory blocks BLK1 to BLKn may be connected to the address decoder 130 through a word line WL, a string select line SSL, and a ground select line GSL, and may be connected to the page buffer 140 through a bit line BL.

The memory cell array 110 may include a plurality of memory cells which are disposed in regions where the plurality of word lines WL and the plurality of bit lines BL intersect with each other. The individual memory cells may be a cell type such as a single-level cell (SLC) type, a multi-level cell (MLC) type, a triple-level cell (TLC) type, a quad-level cell (QLC) type, etc.

The plurality of memory cells included in the memory cell array 110 may be implemented as non-volatile memory cells. For example, the memory cell array 110 may include a two-dimensional (2D) NAND memory array or a three-dimensional vertical NAND (VNAND) memory array.

The voltage generator 120 may receive power voltage PWR, and regulate voltage Vg for memory operation on the basis of a control signal VCTRL, and supply the voltage Vg to the memory cell array 110 through the address decoder 130. For example, the voltage generator 120 may generate read voltage required for a read operation, programming voltage required for a writing operation, a verification voltage required for a verifying operation, an erasing voltage required for an erasing operation, etc.

During a programming operation, the voltage generator 120 may apply a programming voltage to selected word lines of the plurality of word lines WL through the address decoder 130, and apply a programming prohibition voltage to the nonselected word lines (also referred to as unselected word lines). During a programming verifying operation, the voltage generator 120 may apply a programming verifying voltage to selected word lines through the address decoder 130, and apply a verification pass voltage to nonselected word lines.

Nonselected word lines may include dummy word lines. Dummy word lines may refer to word lines on which a programming operation is not performed. Dummy word lines may include word lines adjacent to a string select line SSL, word lines adjacent to a ground select line GSL, and word lines at junctions when the memory cell array 110 has a multi-stack structure having multiple layers stacked. The junctions may refer to parts in the multi-stack structure in which a stack and another stack are in contact with each other.

The voltage generator 120 may apply different verification pass voltages to dummy word lines depending on the locations of selected word lines. The verification pass voltage for dummy word lines among nonselected word lines may be equal to or lower than the verification pass voltage for the other word lines. That is, the voltage generator 120 may apply a dummy voltage to the dummy word lines and may apply a verification pass voltage to unselected word lines other than the dummy word lines that is equal to or lower than the dummy voltage applied to the dummy word lines. For example, in the case of top-to-bottom (T2B) programming, when a selected word line is located relatively high, the voltage generator 120 may apply a first voltage as the verification pass voltage for dummy word lines. When a selected word line is located relatively low, the voltage generator 120 may apply a second voltage higher than the first voltage, as the verification pass voltage for dummy word lines. For example, top-to-bottom (T2B) programming may include programming that progresses from an upper portion of the memory cell array 110 towards a lower portion of the memory cell array 110.

In the case of bottom-to-top (B2T) programming, when a selected word line is located relatively high, the voltage generator 120 may apply a third voltage as the verification pass voltage for dummy word lines. When a selected word line is located relatively low, the voltage generator 120 may apply a fourth voltage lower than the third voltage, as the verification pass voltage for dummy word lines. According to some embodiments, the first voltage and the fourth voltage may be set to the same value. According to some embodiments, the second voltage and the third voltage may be set to the same value. For example, bottom-to-top (B2T) programming may include programming that progresses from a lower portion of the memory cell array 110 towards an upper portion of the memory cell array 110.

The voltage generator 120 may apply the verification pass voltage to dummy word lines at different times during a verifying period. In some embodiments, the voltage generator 120 may apply the verification pass voltage to the dummy word lines in a word line setup section of a verifying period. The word line setup section may be a section in which voltage is applied to word lines. In some embodiments, the voltage generator 120 may apply the verification pass voltage to dummy word lines in a bit line setup section of a verifying period. The bit line setup section may be a section in which voltage is applied to bit lines. A bit line setup section may follow a word line setup section in the verifying period.

The address decoder 130 may be connected to the memory cell array 110 through the word lines WL, the string select lines SSL, and the ground select lines GSL. The address decoder 130 may select at least one of the plurality of memory blocks BLK1 to BLKn by decoding a row address R_ADDR. In other words, the address decoder 130 may select word lines WL, string select lines SSL, and ground select lines GSL, using the row address R_ADDR. The address decoder 130 may supply the voltage Vg supplied from the voltage generator 120 to the word lines WL.

The page buffer 140 may include a plurality of page buffers, which may be connected to the plurality of memory cells through the plurality of bit lines BL, respectively. The page buffer 140 may select at least one bit line of the plurality of bit lines BL, on the basis of a page buffer control signal PBCTR. The page buffer control signal PBCTR may include a column address. The page buffer 140 may operate as a writing driver or a sense amplifier depending on operation modes. For example, during a programming operation, the page buffer 140 may receive data (DATA) from the memory controller 200 through the I/O circuit 150, and apply bit line voltage corresponding to the data (DATA) to selected bit lines. During a read operation, the page buffer 140 may detect data (DATA) stored in the memory cell array 110 by detecting the currents or voltages of selected bit lines, and may provide the data to the memory controller 200 through the I/O circuit 150.

The I/O circuit 150 may be connected to the page buffer 140 through data lines DL. The I/O circuit 150 may provide data (DATA) to the memory cell array 110 through the page buffer 140 or provide data (DATA), output from the memory cell array 110 through the page buffer 140, to the outside (e.g., to a device external to the memory device 100), in response to a control signal IOCTR.

The control logic 160 may generate signals VCTRL, R_ADDR, PBCTR, and IOCTR related to the memory operations, on the basis of at least one of an address (ADDR), a command (CMD), or a control signal (CTRL) received from the memory controller 200. The control logic 160 may provide the individual signals to the voltage generator 120, the address decoder 130, the page buffer 140, and the I/O circuit 150. The control logic 160 may control the overall operation of the memory device 100, using the signals VCTRL, R_ADDR, PBCTR, and IOCTR.

The operations of the memory device 100 may include an erasing loop, a programming loop, and a read operation. Here, the erasing loop may include an erasing operation and an erasing verification operation. The programming loop may include a programming operation and a programming verifying operation.

The control logic 160 may generate at least one of a control signal VCTRL for controlling the voltage generator 120, a control signal PBCTR for controlling the page buffer 140, or a control signal IOCTR for controlling the I/O circuit 150, on the basis of a command (CMD). Also, the control logic 160 may generate a row address R_ADDR and a column address on the basis of an address (ADDR). The control logic 160 may output the row address R_ADDR to the address decoder 130, and may output the column address to the page buffer 140.

The control logic 160 may generate a control signal VCTRL for a programming verifying operation. In other words, the control logic 160 may generate a control signal VCTRL such that the voltage generator 120 outputs verification voltage and verification pass voltage. At this time, the control logic 160 may generate a control signal VCTRL such that the voltage generator 120 outputs different verification pass voltages to dummy word lines, depending on the locations of selected word lines. Also, the control logic 160 may generate row addresses R_ADDR depending on the locations of selected word lines. In the case of T2B programming, the control logic 160 may generate a control signal VCTRL, such that in the case of selected word lines at relatively high locations, the voltage generator 120 applies the first voltage to dummy word lines, and in the case of selected word lines at relatively low locations, the voltage generator applies the second voltage higher than the first voltage to dummy word lines. Also, in the case of B2T programming, the control logic 160 may generate a control signal VCTRL, such that in the case of selected word lines at relatively high locations, the voltage generator 120 applies the third voltage to dummy word lines, and in the case of selected word lines at relatively low locations, the voltage generator applies the fourth voltage lower than the third voltage to data lines.

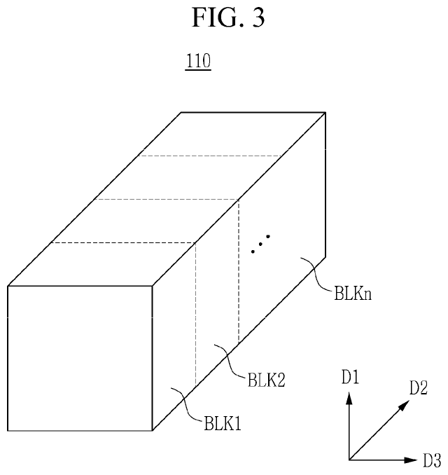

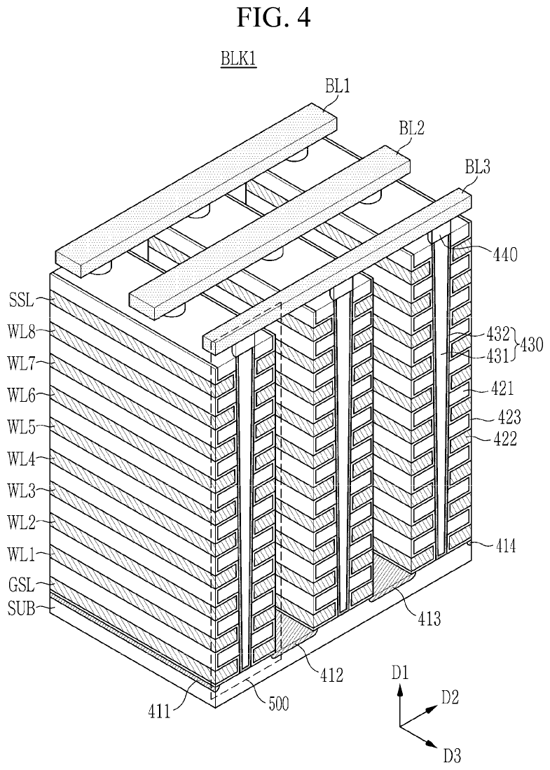

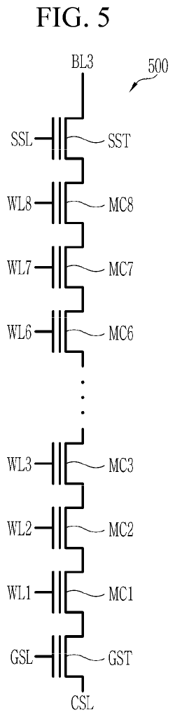

FIG. 3 is a schematic diagram for explaining the memory cell array according to some embodiments, FIG. 4 is a perspective cross-sectional view for explaining one memory block of the memory cell array according to some embodiments, and FIG. 5 is an electric equivalent circuit diagram of a part of the memory block of FIG. 4.

Referring to FIGS. 3 to 5, each of the plurality of memory blocks BLK1 to BLKn may be formed in a three-dimensional structure on a substrate SUB. For example, a plurality of memory NAND strings included in each of the plurality of memory blocks BLK1 to BLKn may be formed in a direction D1 perpendicular to the substrate SUB. The substrate SUB may be formed along a direction D2 and a direction D3. The plurality of memory NAND strings may be on the substrate SUB.

The memory block BLK1 may be formed in the direction perpendicular to the substrate SUB (e.g., the direction D1). The substrate SUB may be a p-type silicon substrate. The substrate SUB may include n-type doped regions 411 to 414 doped differently from the substrate SUB. Alternatively, the substrate SUB may be an n-type silicon substrate, and may include p-type doped regions 411 to 414. The doped regions 411 to 414 may refer to common source regions (CSRs). The plurality of CSRs may be connected in common to constitute a common source line (CSL).

On the substrate SUB, cell insulating layers 421 and gate electrodes 422 may be alternately stacked. Between the cell insulating layers 421 and the gate electrodes 422, data storage films 423 may be formed.

Pillars 430 may pass through the cell insulating layers 421 and the gate electrodes 422 in the vertical direction (e.g., the direction D1). The pillars 430 may pass through the cell insulating layers 421 and the gate electrodes 422 so as to be connected to the substrate SUB. The pillars 430 may be formed in a V-shape. In other words, the pillars 430 may pass through the cell insulating layers 421 and the gate electrodes 422 and narrow as they get closer to the substrate SUB. The pillars 430 may include inner parts 431 made of an insulating material such as silicon oxide, and outer parts 432 made of a channel semiconductor. Due to features of the semiconductor process, channels may narrow as they get closer to the substrate SUB in the direction D1 perpendicular to the substrate SUB, and widen as they get closer to the bit lines BL1 to BL3. In other words, the outer parts 432 functioning as channels may have a V-shape.

The gate electrode 422 of the memory block BLK1 may be connected to a ground select line GSL, the word lines WL1 to WL8, or a string select line SSL. Also, the pillars 430 may be connected to the bit lines BL1 to BL3 through drains 440.

FIG. 5 shows an electric equivalent circuit diagram of a part 500 of the memory block BLK1 of FIG. 4. The part 500 may correspond to a memory NAND string. Referring to FIGS. 4 and 5, the first memory block BLK1 may include a memory NAND string connected between the bit line BL3 and a common source line (CSL). The memory NAND string may include a string selection transistor SST, a plurality of memory cells MC1 to MC8, and a ground selection transistor GST. The memory block BLK1 may further include a plurality of memory NAND strings connected between the bit lines BL1 and BL2 and the common source line (CSL).

The gate of the string selection transistor SST may be connected to a string select line SSL. The gate of the ground selection transistor GST may be connected to a ground select line GSL. The string selection transistor SST may be connected to the bit line BL3, and the ground selection transistor GST may be connected to the common source line (CSL).

The plurality of memory cells MC1 to MC8 may be connected to the corresponding word lines WL1 to WL8, respectively. The word lines WL1 to WL8 may correspond to gate lines. Among the word lines WL1 to WL8, the word lines WL1 and WL8 may be dummy word lines. In other words, dummy word lines may include the word line WL1 adjacent to the ground select line GSL, and the word line WL8 adjacent to the string select line SSL. In some embodiments, when the first memory block BLK1 has a multi-stack structure, dummy word lines may further include word lines of junctions. Although it is shown in FIGS. 4 and 5 for ease of explanation that eight word lines WL1 to WL8 and eight memory cells MC1 to MC8 are implemented, the numbers of word lines and memory cells are not necessarily limited thereto, and more than eight word lines and more than eight memory cells may be implemented depending on the number of layers set to be stacked in the manufacturing process.

In the plurality of memory NAND strings included in the first memory block BLK1, word lines located at the same height may be connected in common, and the ground select lines GSL and the string select lines SSL may be separated from one another. As used herein, “a word line located at a height” (or similar language) means the height of the word line in a vertical direction (e.g., the direction D1) from a surface of the substrate SUB. In other words, a height of a word line may be relative to the substrate SUB.

For a memory operation, the voltage generator 120 in FIG. 2 may apply voltage to the ground select line GSL, the word lines WL1 to WL8, and the string select line SSL through the address decoder 130. After a programming operation is completed on selected word lines, when a programming verifying operation is performed, the voltage generator 120 may apply a verification voltage to the selected word lines and apply a verification pass voltage to the nonselected word lines. At this time, the voltage generator 120 may apply a dummy voltage to the dummy word lines WL1 and WL8 among the nonselected word lines. The voltage generator 120 may apply different dummy voltages depending on the locations of selected word lines.

For example, in the case of T2B programming, when a word line (for example, the reference symbol “WL7”) at a relatively high location is selected, since the word lines WL1 to WL6 at locations lower than the location of the word line WL7 have not undergone programming yet and are in an erased state, a relatively high current may flow in the word line WL7. Accordingly, the voltage generator 120 may apply the verification voltage to the word line WL7, and apply the verification pass voltage to the word lines WL2 to WL6, and apply a first dummy voltage to the dummy word lines WL1 and WL8. Further, in the case of T2B programming, when a word line at a relatively low location (for example, the reference symbol “WL2”) is selected, a relatively low current may flow in the word line WL2 due to a voltage drop. Accordingly, the voltage generator 120 may apply the verification voltage to the word line WL2, and apply the verification pass voltage to the word lines WL3 to WL7, and apply a second dummy voltage to the dummy word lines WL1 and WL8. The second dummy voltage may be higher than the first dummy voltage, and be equal to the verification pass voltage or lower than the verification pass voltage. As described above, in the case of T2B programming, the voltage generator 120 may apply a low voltage to the dummy word lines WL1 and WL8 when a word line at a high location is selected, and apply a high voltage to the dummy word lines WL1 and WL8 when a word line at a low location is selected. The control logic 160 in FIG. 2 may control the voltage generator 120 by a control signal VCTRL such that the voltage generator outputs different voltages. For example, a height of a word line may be relative to the substrate SUB in a vertical direction (e.g., the direction D1). For example, T2B programming may include programming that progresses from a word line in an upper portion of the first memory block BLK1 towards a word line in a lower portion of the first memory block BLK1. That is, the T2B programming may include programming that progresses towards the substrate SUB.

In the case of B2T programming, when a word line at a relatively high location (for example, the reference symbol “WL7”) is selected, a relatively low current may flow in the word line WL7 due to a voltage drop. Accordingly, the voltage generator 120 may apply the verification voltage to the word line WL7, and apply the verification pass voltage to the word lines WL2 to WL6, and apply a third dummy voltage to the dummy word lines WL1 and WL8. The third dummy voltage may be equal to the verification pass voltage or lower than the verification pass voltage. Further, in the case of B2T programming, when a word line at a relatively low location (for example, the reference symbol “WL2”) is selected, the word lines WL3 to WL8 at locations higher than the location of the word line WL2 have not undergone programming yet and are in an erased state, and a relatively high current may flow in the word line WL2. For this reason, the voltage generator 120 may apply the verification voltage to the word line WL2, and apply the verification pass voltage to the word lines WL3 to WL7, and apply a fourth dummy voltage to the dummy word lines WL1 and WL8. The fourth dummy voltage may be lower than the third dummy voltage. In some embodiments, the first dummy voltage may be equal to the fourth dummy voltage, and the second dummy voltage may be equal to the third dummy voltage. As described above, in the case of B2T programming, the voltage generator 120 may apply a high voltage to the dummy word lines WL1 and WL8 when a word line at a high location is selected, and apply a low voltage to the dummy word lines WL1 and WL8 when a word line at a low location is selected. The control logic 160 in FIG. 2 may control the voltage generator 120 by a control signal VCTRL such that the voltage generator outputs different voltages. For example, B2T programming may include programming that progresses from a word line in a lower portion of the first memory block BLK1 towards a word line in an upper portion of the first memory block BLK1. That is, the B2T programming may include programming that progresses away from the substrate SUB.

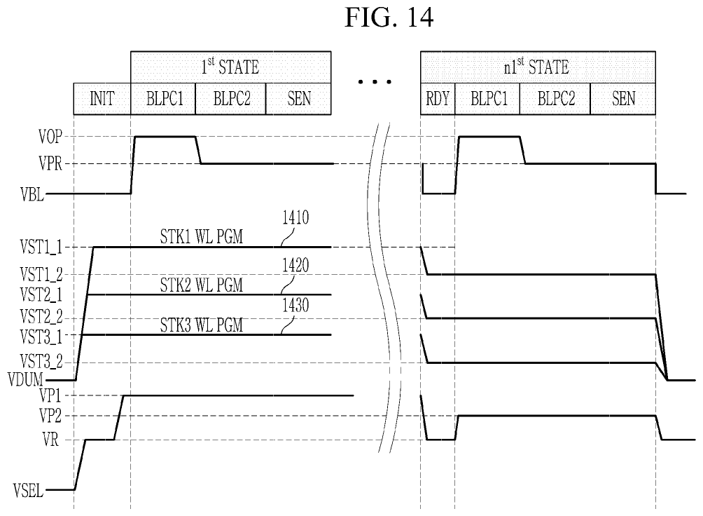

In some embodiments, the voltage generator 120 may apply a dummy voltage to the dummy word lines WL1 and WL8 at different times. In some embodiments, the voltage generator 120 may apply a dummy voltage in a word line setup section. In some embodiments, the voltage generator 120 may apply a dummy voltage in a bit line setup section following a word line setup section. In this case, the voltage generator 120 may maintain or decrease the voltage applied in the word line setup section, in the bit line setup section. The times when the voltage generator 120 applies a dummy voltage will be described below with reference to FIGS. 14 to 19.

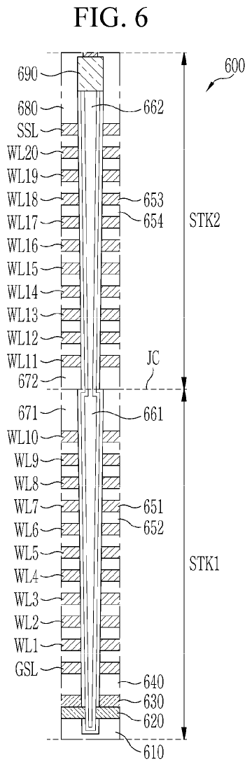

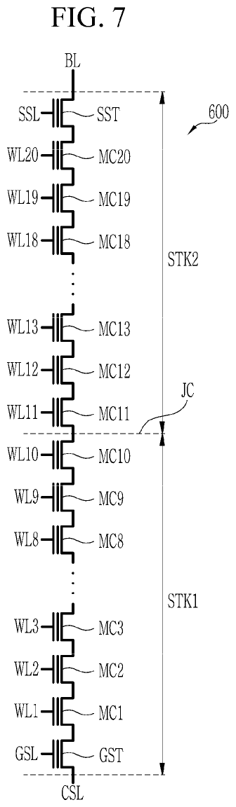

FIG. 6 is a drawing for explaining a memory NAND string of the multi-stack structure according to some embodiments, and FIG. 7 is an electric equivalent circuit diagram of the memory NAND string of FIG. 6.

Referring to FIG. 6, a memory NAND string 600 according to some embodiments may be a multi-stack structure including a first stack STK1 and a second stack STK2. Due to the multi-stack structure, the numbers of gate electrodes and memory cells in the memory NAND string 600 may be increased. In other words, the memory NAND string 600 has a stable structure capable of increasing the data storage capacity. The first stack STK1 and the second stack STK2 may correspond to a first channel structure and a second channel structure, respectively. The first channel structure and the second channel structure may be formed so as to pass through a gate stack structure.

Although it is shown in FIG. 6 that the memory NAND string 600 includes two stacks STK1 and STK2, the present disclosure is not necessarily limited thereto, in some embodiments, a memory NAND string 600 may be configured to include three or more stacks.

The first stack STK1 may include a substrate 610, horizontal conductive layers 620 and 630, an interlayer insulating layer 640, gate electrodes 651, cell insulating layers 652, channel structures 661, and an upper insulating layer 671. The substrate 610 may be a semiconductor substrate made of a semiconductor material. For example, the substrate 610 may be a semiconductor substrate including a semiconductor layer made of silicon, germanium, silicon-germanium, silicon-on-insulator, germanium-on-insulator, etc., on a base substrate.

The horizontal conductive layers 620 and 630 may contain a semiconductor material (for example, polycrystalline silicon). For example, the first horizontal conductive layer 620 may be a polycrystalline silicon layer doped with impurities, and the second horizontal conductive layer 630 may be a polycrystalline silicon layer doped with impurities or a layer containing impurities diffused from the first horizontal conductive layer 620. However, the present disclosure is not necessarily limited thereto, and the second horizontal conductive layer 630 may be formed on an insulating material. In some embodiments, the second horizontal conductive layer 630 may not be separately provided.

The first horizontal conductive layer 620 may function as a common source line together with the substrate 610. In some embodiments, the first horizontal conductive layer 620 may be replaced with a horizontal insulating layer. The second horizontal conductive layer 630 may be located on the first horizontal conductive layer 620.

The interlayer insulating layer 640 may be located between the gate electrodes 651 and the second horizontal conductive layer 630. The interlayer insulating layer 640 may be formed of an insulating material containing silicon oxide, silicon nitride, silicon oxynitride, a low-k material having a dielectric constant smaller than that of silicon oxide, or a combination thereof. Similarly, the cell insulating layers 652, the upper insulating layer 671, an interlayer insulating layer 672, cell insulating layers 654, and an upper insulating layer 680 may contain various insulating materials. The thicknesses of the interlayer insulating layer 640, the cell insulating layers 652, the upper insulating layer 671, the interlayer insulating layer 672, the cell insulating layers 654, and the upper insulating layer 680 may be changed.

The gate electrodes 651 may contain various conductive materials. As an example, the gate electrodes 651 may contain a metal material such as tungsten (W), copper (Cu), aluminum (Al), etc. As another example, the gate electrodes 651 may contain polycrystalline silicon, metal nitride (such as titanium nitride (TiN), tantalum nitride (TaN), etc.), or a combination thereof. The gate electrodes 651 may be stacked alternately with the cell insulating layers 652. The cell insulating layers 652 may contain various insulating materials. The numbers of gate electrodes 651 and cell insulating layers 652 may be determined depending on the data storage capacity of the memory device. The gate electrodes 651 may be connected to a ground select line GSL and word lines WL1 to WL10, respectively.

The channel structure 661 may be formed so as to pass through the gate stack structure. The channel structure 661 may include a channel layer, a gate dielectric layer located on the channel layer, and a core insulating layer located inside the channel layer. In FIG. 6, the channel structure 661 of the first stack STK1 and a channel structure 662 of the second stack STK2 may have inclined side surfaces such that the channel structures 661 and 662 narrow as they get closer to the substrate 610. Accordingly, at the part where the first stack STK1 and the second stack STK2 are connected, a curved part may be provided due to the difference in width. In some embodiments, the first stack STK1 and the second stack STK2 may have inclined side surfaces continuously connected without a curved part.

The upper insulating layer 671 may be an interlayer insulating layer located between the gate stack structure of the first stack STK1 and the gate stack structure of the second stack STK2. The upper insulating layer 671 may be bonded to the interlayer insulating layer 672 of the second stack STK2 at a junction JC. In other words, the first stack STK1 and the second stack STK2 may be bonded so as to form the junction JC. The upper insulating layer 671 may have a thickness different from that of the cell insulating layers 652.

The second stack STK2 may include a structure similar to that of the first stack STK1. The second stack STK2 may include the interlayer insulating layer 672, gate electrodes 653, the cell insulating layers 654, the channel structure 662, the upper insulating layer 680, and a channel pad 690.

The interlayer insulating layer 672 may be bonded to the upper insulating layer 671 of the first stack STK1 at the junction JC. The gate electrodes 653 and the cell insulating layers 654 may be alternately stacked on the interlayer insulating layer 672. The gate electrodes 653 may be connected to a string select line SSL and word lines WL11 to WL20, respectively.

The channel structure 662 may be formed so as to pass through the gate stack structure. The channel structure 662 may include a channel layer, a gate dielectric layer located on the channel layer, and a core insulating layer located inside the channel layer.

The upper insulating layer 680 may be located at the top of the gate stack structure. The upper insulating layer 680 may constitute a part of or the whole of a cell region insulating layer located over the upper part of the memory NAND string 600.

The channel pad 690 may be disposed on the channel structure 662. The channel pad 690 may be disposed so as to cover the upper surface of the core insulating layer of the channel structure 662 and be electrically connected to the channel layer. The channel pad 690 may contain a conductive material, for example, polycrystalline silicon doped with impurities, but is not limited thereto.

Although it is shown in FIG. 6 for ease of explanation that the first stack STK1 and the second STK2 each include ten word lines WL1 to WL10 and WL11 to WL20, respectively, and ten memory cells MC1 to MC10 and MC11 to MC20 (see FIG. 7), respectively, the present disclosure is not necessarily limited thereto, and more than ten word lines and more than ten memory cells may be implemented depending on the number of layers set to be stacked in the manufacturing process.

FIG. 7 is an electric equivalent circuit diagram of the memory NAND string 600 of FIG. 6. Referring to FIGS. 6 and 7, the memory NAND string 600 may include the string selection transistor SST, the plurality of memory cells MC1 to MC20, and the ground selection transistor GST. The memory NAND string 600 may include the first stack STK1 including the ground selection transistor GST and the plurality of memory cells MC1 to MC10, and the second stack STK2 including the string selection transistor SST and the plurality of memory cells MC11 to MC20.

The gate of the string selection transistor SST may be connected to a string select line SSL. The gate of the ground selection transistor GST may be connected to a ground select line GSL. The string selection transistor SST may be connected to a bit line BL, and the ground selection transistor GST may be connected to a common source line (CSL).

The plurality of memory cells MC1 to MC20 may be connected to the corresponding word lines WL1 to WL20, respectively. The word lines WL1 to WL20 may correspond to gate lines. Among the word lines WL1 to WL20, the word lines WL1, WL10, WL11, and WL20 may be dummy word lines. In other words, dummy word lines may include the word line WL1 adjacent to the ground select line GSL, the word lines WL10 and WL11 adjacent to the junction JC, and the word line WL20 adjacent to the string select line SSL. In some embodiments, dummy word lines may include two or more word lines adjacent to the ground select line GSL, three or more word lines adjacent to the junction JC, or two or more word lines adjacent to the string select line SSL.

For a memory operation, the voltage generator 120 in FIG. 2 may apply voltage to the ground select line GSL, the word lines WL1 to WL20, and the string select line SSL through the address decoder 130. After a programming operation is completed on selected word lines, when a programming verifying operation is performed, the voltage generator 120 may apply a verification voltage to the selected word lines and apply a verification pass voltage to the nonselected word lines. At this time, the voltage generator 120 may apply a dummy voltage to the dummy word lines WL1, WL10, WL11, and WL20 among the nonselected word lines. The voltage generator 120 may apply different dummy voltages depending on the locations of selected word lines.

For example, in the case of T2B programming, when a word line (for example, the reference symbol “WL19”) at a relatively high location is selected, since the word lines WL1 to WL18 at locations lower than the location of the word line WL19 have not undergone programming yet and are in an erased state, a relatively high current may flow in the word line WL19. Accordingly, the voltage generator 120 may apply the verification voltage to the word line WL19, and apply the verification pass voltage to the word lines WL2 to WL9 and WL12 to WL18, and apply the first dummy voltage to the dummy word lines WL1, WL10, WL11, and WL20. Further, in the case of T2B programming, when a word line at a relatively low location is selected, a relatively low current may flow in the word line due to a voltage drop. A word line at a relatively low location may refer to a word line in the same stack (the second stack STK2) (for example, the word line WL13), and may refer to a word line in another stack (the first stack STK1) (for example, the word line WL8). For example, a location of a word line may be relative to the substrate 610 in a vertical direction. For example, T2B programming may include programming that progresses from a word line in an upper portion of the memory NAND string 600 towards a word line in a lower portion of the memory NAND string 600. That is, the T2B programming may include programming that progresses towards the substrate 610.

In some embodiments, when a word line at a relatively low location in the same stack (the second stack STK2) (for example, the word line WL13) is selected, the voltage generator 120 may apply the verification voltage to the word line WL13, and apply the verification pass voltage to the word lines WL2 to WL9, WL12, and WL14 to WL19, and apply the second dummy voltage to the dummy word lines WL1, WL10, WL11, and WL20. The second dummy voltage may be higher than the first dummy voltage.

In some embodiments, when a word line at a relatively low location in another stack (the first stack STK1) (for example, the word line WL8) is selected, the voltage generator 120 may apply the verification voltage to the word line WL8, and apply the verification pass voltage to the word lines WL2 to WL7, WL9, and WL12 to WL19, and apply the third dummy voltage to the dummy word lines WL1, WL10, WL11, and WL20. The third dummy voltage may be higher than the first dummy voltage and the second dummy voltage, and be equal to the verification pass voltage or lower than the verification pass voltage. Since the first stack STK1 is located beneath the second stack STK2, when any word line in the first stack STK1 is selected, a higher dummy voltage may be applied as compared to when a word line in the second stack STK2 is selected.

As described above, in the case of T2B programming, the voltage generator 120 may apply a low voltage to the dummy word lines WL1, WL10, WL11, and WL20 when a word line at a high location is selected, and apply a high voltage to the dummy word lines WL1, WL10, WL11, and WL20 when a word line at a low location is selected. The control logic 160 in FIG. 2 may control the voltage generator 120 by a control signal VCTRL such that the voltage generator outputs different voltages.

In the case of B2T programming, when a word line at a relatively high location (for example, the reference symbol “WL19”) is selected, a relatively low current may flow in the word line WL19 due to a voltage drop. Accordingly, the voltage generator 120 may apply the verification voltage to the word line WL19, and apply the verification pass voltage to the word lines WL2 to WL9, and WL12 to WL18, and apply the fourth dummy voltage to the dummy word lines WL1, WL10, WL11, and WL20. The fourth dummy voltage may be equal to the verification pass voltage or lower than the verification pass voltage. Further, in the case of B2T programming, when a word line at a relatively low location is selected, the word lines at locations higher than the word line at the low location have not undergone programming yet and are in an erased state, a relatively high current may flow in the word line at the relatively low location. A word line at a relatively low location may refer to a word line in the same stack (the second stack STK2) (for example, the word line WL13), and may refer to a word line in another stack (the first stack STK1) (for example, the word line WL8). For example, B2T programming may include programming that progresses from a word line in a lower portion of the memory NAND string 600 towards a word line in an upper portion of the memory NAND string 600. That is, the B2T programming may include programming that progresses away from the substrate 610.

In some embodiments, when a word line at a relatively low location in the same stack (the second stack STK2) (for example, the word line WL13) is selected, the voltage generator 120 may apply the verification voltage to the word line WL13, and apply the verification pass voltage to the word lines WL2 to WL9, WL12, and WL14 to WL19, and apply a fifth dummy voltage to the dummy word lines WL1, WL10, WL11, and WL20. The fifth dummy voltage may be lower than the fourth dummy voltage.

In some embodiments, when a word line at a relatively low location in another stack (the first stack STK1) (for example, the word line WL8) is selected, the voltage generator 120 may apply the verification voltage to the word line WL8, and apply the verification pass voltage to the word lines WL2 to WL7, WL9, and WL12 to WL19, and apply a sixth dummy voltage to the dummy word lines WL1, WL10, WL11, and WL20.

The sixth dummy voltage may be lower than the fourth dummy voltage and the fifth dummy voltage. Since the first stack STK1 is located beneath the second stack STK2, when any word line in the first stack STK1 is selected, a lower dummy voltage may be applied as compared to when a word line in the second stack STK2 is selected.

As described above, in the case of B2T programming, the voltage generator 120 may apply a high voltage to the dummy word lines WL1, WL10, WL11, and WL20 when a word line at a high location is selected, and apply a low voltage to the dummy word lines WL1, WL10, WL11, and WL20 when a word line at a low location is selected. The control logic 160 in FIG. 2 may control the voltage generator 120 by a control signal VCTRL such that the voltage generator outputs different voltages.

In some embodiments, the voltage generator 120 may apply a dummy voltage to the dummy word lines WL1, WL10, WL11, and WL20 at different times. In some embodiments, the voltage generator 120 may apply a dummy voltage in a word line setup section. In some embodiments, the voltage generator 120 may apply a dummy voltage in a bit line setup section following a word line setup section. In this case, the voltage generator 120 may maintain or decrease the voltage applied in the word line setup section, in the bit line setup section. The times when the voltage generator 120 applies a dummy voltage will be described below with reference to FIGS. 14 to 19.

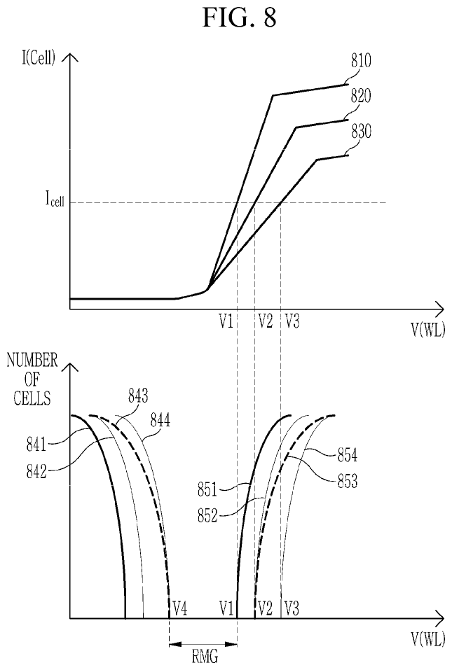

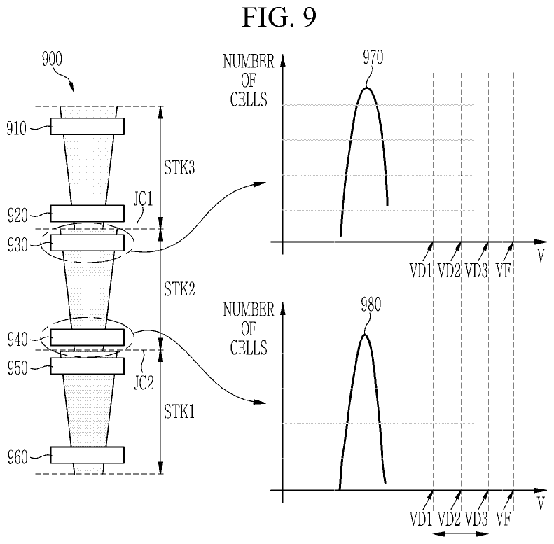

FIG. 8 is graphs for explaining cell distribution change during the operation of the memory device according to some embodiments, and FIG. 9 is graphs for explaining a change in dummy voltage which is applied by the memory device according to some embodiments.

If data is programmed in the memory device 100 shown in FIGS. 1 and 2 in the order from top to bottom (e.g., T2B programming), cell distributions as shown in FIG. 8 may be shown. Such a cell distribution may shift depending on the pattern of the memory cells (for example, whether programming has been performed).

Referring to FIG. 8, in the upper graph, the x-axis represents voltage which is applied to a word line, and the y-axis represents current which flows in a cell. A graph 810 represents the relationship between voltage and current when a selected word line at a relatively high location is verified after programming. When the selected word line is verified, word lines at locations lower than the location of the selected word line may be in an erased state. Therefore, the graph 810 may have a relatively steep slope. From the graph 810, it can be seen that a voltage V1 is required for a current I_{cell}.

A graph 820 represents the relationships between voltage and current when data on a selected word line is read in a state where a relatively small amounts of data has been programmed on word lines located lower than the selected word line. Due to a voltage drop on the word lines at the lower locations on which the relatively small amount of data has been programmed, the graph 820 may have a more gradual slope as compared to the graph 810. From the graph 820, it can be seen that a voltage V2 higher than the voltage V1 is required for the current I_{cell}.

A graph 830 represents the relationships between voltage and current when data on a selected word line is read in a state where a relatively large amount of data has been programmed on word lines located lower than the selected word line. Due to a voltage drop on the word lines at the lower locations on which the relatively large amount of data has been programmed, the graph 830 may have a more gradual slope as compared to the graph 820. From the graph 830, it can be seen that a voltage V3 higher than the voltage V1 and the voltage V2 is required for the current I_{cell}.

It can be seen that a voltage (V1, V2, or V3) to be applied to a selected word line differs depending on the pattern of memory cells corresponding to word lines located lower than the selected word line (or, in the case of B2T programming, word lines located higher than the selected word line). In order to overcome such a cell distribution shift depending on the pattern of memory cells, programming parameters are set. Among various types of programming parameters, verification levels define the start positions of individual states in a cell distribution. If the gap between the verification levels of two adjacent states is wide, the margin of the cell distribution between the two adjacent states is wide, which can be seen as stronger against memory cell patterns which cause cell distribution shifts.

However, from the lower graph in FIG. 8, it can be found that a read margin RMG representing the width between voltages V1 and V4 determined on the basis of the state graphs 841 to 844 and 851 to 854 of memory cells have significantly narrowed. The memory device 100 according to embodiments of the present disclosure may apply different dummy voltages to dummy word lines depending on the locations of selected word lines. Accordingly, the graph 810 has a gradual slope. Therefore, the memory device 100 can secure a wider read margin RMG. Accordingly, reliability can be improved despite cell distribution shifts depending on memory cell patterns.

Referring to FIG. 9, a memory device 100 according to some embodiments may include a memory NAND string 900. The memory NAND string 900 may be a multi-stack structure of a first stack STK1, a second stack STK2, and a third stack STK3. The memory NAND string 900 may include dummy word lines 910 to 960. The dummy word lines 910 to 960 may include a word line 910 adjacent to a string select line, word lines 920 and 930 at a junction JC1 (e.g., adjacent to a junction JC1), word lines 940 and 950 at a junction JC2 (e.g., adjacent to a junction JC2), and a word line 960 adjacent to a ground select line. A cell distribution graph 970 related to the dummy word line 930 of the dummy word lines 910 to 960 is shown in the upper part of the drawing, and a cell distribution graph 980 related to the dummy word line 940 is shown in the lower part of the drawing.

The memory device 100 may apply different levels of verification voltages depending on verification states to selected word lines for a verifying operation (also referred to as a verifying period). For example, the memory device 100 may apply a first verification voltage in a first state verification section, and apply a second verification voltage lower than the first verification voltage in a second state verification section following the first state verification section. Further, the memory device 100 may apply a dummy voltage VD1, VD2, or VD3 to the dummy word lines 910 to 960, and apply a verification pass voltage VF to nonselected word lines except for the dummy word lines 910 to 960. The verification voltages may be lower than the verification pass voltage VF, and the dummy voltages VD1, VD2, and VD3 may be lower than the verification pass voltage VF. In this case, the memory device 100 may apply the dummy voltage VD1, VD2, or VD3 to the dummy word lines 910 to 960, depending on the location of the selected word line. In some embodiments, the memory device 100 may apply the dummy voltage VD1, VD2, or VD3 to the dummy word lines 910 to 960, on the basis of which of the stacks STK1, STK2, and STK3 the selected word line belongs to. For example, when the memory device 100 performs T2B programming, the memory device 100 may apply the dummy voltage VD3 if a selected word line belongs to the first stack STK1, and apply the dummy voltage VD2 if a selected word line belongs to the second stack STK2, and apply the dummy voltage VD1 if a selected word line belongs to the third stack STK3. Further, when the memory device 100 performs B2T programming, the memory device 100 may apply the dummy voltage VD1 if a selected word line belongs to the first stack STK1, and apply the dummy voltage VD2 if a selected word line belongs to the second stack STK2, and apply the dummy voltage VD3 if a selected word line belongs to the third stack STK3. In other words, in the case of T2B programming, the memory device 100 may apply a low dummy voltage with respect to a selected word line at a high location, and apply a high dummy voltage with respect to a selected word line at a low location. Further, in the case of B2T programming, the memory device 100 may apply a high dummy voltage with respect to a selected word line at a high location, and apply a low dummy voltage with respect to a selected word line at a low location.

In some embodiments, the memory device 100 may apply the dummy voltage VD1, VD2, or VD3 to the dummy word lines 910 to 960 on the basis of where a selected word line is located in the stack STK1, STK2, or STK3. For example, when the memory device 100 performs T2B programming, the memory device 100 may apply the dummy voltage VD1 if a selected word line is located in the upper part of the first stack STK1, and apply the dummy voltage VD2 if a selected word line is located in the middle part of the first stack STK1, and apply the dummy voltage VD3 if a selected word line is located in the bottom part of the first stack STK1. Further, when the memory device 100 performs B2T programming, the memory device 100 may apply the dummy voltage VD3 if a selected word line is located in the upper part of the first stack STK1, and apply the dummy voltage VD2 if a selected word line is located in the middle part of the first stack STK1, and apply the dummy voltage VD1 if a selected word line is located in the lower part of the first stack STK1. In other words, in the case of T2B programming, the memory device 100 may apply a low dummy voltage with respect to a selected word line at a high location in the same stack (for example, the first stack STK1), and apply a high dummy voltage with respect to a selected word line at a low location in the stack. Further, in the case of B2T programming, the memory device 100 may apply a high dummy voltage with respect to a selected word line at a high location in the same stack, and apply a low dummy voltage with respect to a selected word line at a low location in the stack.

The dummy voltage when a selected word line is located in the upper part, middle part, or lower part of the first stack STK1 has been described above; however, the same description can be applied to the second stack STK2 and the third stack STK3. Even in this case, in the case of T2B programming, the dummy voltage when a word line in the first stack STK1 is selected may be higher than the dummy voltage when a word line in the second stack STK2 or the third stack STK3 is selected. Similarly, in the case of T2B programming, the dummy voltage when a word line in the second stack STK2 is selected may be lower than the dummy voltage when a word line in the first stack STK1 is selected, and be higher than the dummy voltage when a word line in the third stack STK3 is selected.

In some embodiments, the memory device 100 may apply the dummy voltage VD1, VD2, or VD3 to the dummy word lines 910 to 960 according to temperature. For example, the memory device 100 may apply a low dummy voltage (for example, the dummy voltage VD1 or VD2) when the temperature is high, and apply a high dummy voltage (for example, the dummy voltage VD3) when the temperature is low. For example, the memory device 100 may apply the dummy voltage VD3 when the temperature is lower than a first reference value, apply the dummy voltage VD2 when the temperature exceeds the first reference value, and apply the dummy voltage VD1 when the temperature exceeds a second reference value. Here, the second reference value may be larger than the first reference value.

In some embodiments, the memory device 100 may apply the dummy voltage VD1, VD2, or VD3 to the dummy word lines 910 to 960, depending on a program/erase cycle (P/E cycle). For example, the memory device 100 may apply a low dummy voltage (for example, the dummy voltage VD1) when the P/E cycle is low, and apply a higher dummy voltage (for example, the dummy voltage VD2 or VD3) as the P/E cycle increases. For example, the memory device 100 may apply the dummy voltage VD1 when the P/E cycle is lower than a first reference value, apply the dummy voltage VD2 when the P/E cycle exceeds the first reference value, and apply the dummy voltage VD3 when the P/E cycle exceeds a second reference value. Here, the second reference value may be larger than the first reference value.

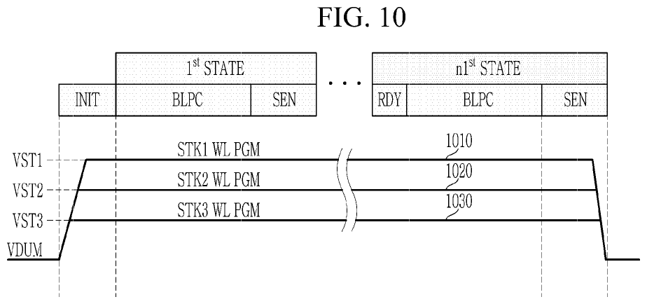

FIG. 10 is a drawing for explaining a configuration in which the memory device according to some embodiments applies dummy voltage.

Referring to FIG. 10, the memory device according to some embodiments may perform T2B programming. The memory device may perform a verifying operation after performing a programming operation on a selected word line. The verifying operation may include a first state section in which the memory device performs verification by applying the first verification voltage to the selected word line, and a second state section in which the memory device performs verification by applying the second verification voltage, lower than the first verification voltage, to the selected word line. In

FIG. 10, the second state section is denoted by “non-first state” (n1^{st} STATE) meaning that the second state section is not the first state section. The verifying operation (e.g., a verifying period) may include an initialization section INIT in which the memory device performs word line setup, a bit line precharge section BLPC in which the memory device performs bit line setup such that cell current flows, and a sensing section SEN after cutting off the voltage to be applied to the bit lines. The second state section may include a readying section RDY in which the memory device initializes the previous verification and is readied for the subsequent verification. Prior to the initialization section INIT, the memory device may have completed a programming operation.

The memory device may determine a dummy voltage VDUM depending on the location of a selected word line, and apply the determined dummy voltage VDUM to dummy word lines. The dummy word lines may include a word line adjacent to a string select line, word lines adjacent to a junction, and a word line adjacent to a ground select line. The memory device may determine a dummy voltage VDUM depending on which of the plurality of stacks STK1 to STK3 a selected word line is located in. The memory device may be a multi-stack structure including the first stack STK1, the second stack STK2, and the third stack STK3. In this case, the first stack STK1 and the second stack STK2 may be bonded, and the second stack STK2 and the third stack STK3 may be bonded. The second stack STK2 may be located on the first stack STK1, and the third stack STK3 may be located on the second stack STK2.

For example, when a selected word line is located in the first stack STK1, the memory device may apply the dummy voltage VDUM of VST1 to the dummy word lines as shown by a graph 1010. The memory device may apply the dummy voltage VDUM of VST1 to the dummy word lines in the initialization section INIT. The memory device may maintain the dummy voltage VDUM of VST1 until the verifying operation ends. In other words, the memory device may keep applying the dummy voltage VDUM of VST1 in the bit line precharge section BLPC and the sensing section SEN of the first state section, and the readying section RDY and the bit line precharge section BLPC of the second state section. The memory device may stop applying the dummy voltage VDUM of VST1 in the sensing section SEN of the second state section, and end the verifying operation.

Similarly, the memory device may apply the dummy voltage VDUM of VST2 to dummy word lines as shown by a graph 1020 when a selected word line is located in the second stack STK2, and apply the dummy voltage VDUM of VST3 to dummy word lines as shown by a graph 1030 when a selected word line is located in the third stack STK3. Here, VST1 may be larger than VST2 and VST3, and VST2 may be larger than VST3.

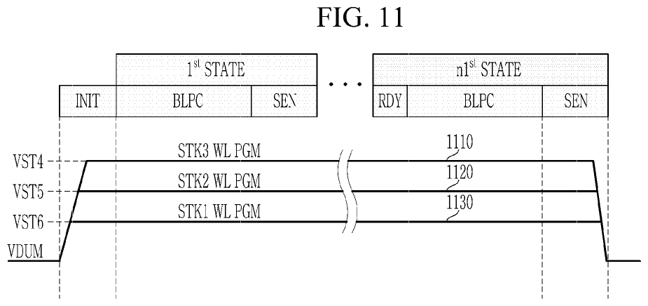

FIG. 11 is a drawing for explaining a configuration in which the memory device according to some embodiments applies dummy voltage.

Referring to FIG. 11, the memory device according to some embodiments may perform B2T programming. After performing a programming operation on a selected word line, the memory device may perform a verifying operation through an initialization section INIT, a first state section, and a second state section. For ease of explanation, a redundant description of the same contents as those related to FIG. 10 will not be made.

The memory device may determine a dummy voltage VDUM depending on the location of a selected word line, and apply the determined dummy voltage VDUM to dummy word lines. The memory device may determine a dummy voltage VDUM depending on which of the plurality of stacks STK1 to STK3 a selected word line is located in. The memory device may be a multi-stack structure including the first stack STK1, the second stack STK2, and the third stack STK3. In this case, the first stack STK1 and the second stack STK2 may be bonded, and the second stack STK2 and the third stack STK3 may be bonded. The second stack STK2 may be located on the first stack STK1, and the third stack STK3 may be located on the second stack STK2.

For example, when a selected word line is located in the first stack STK1, the memory device may apply the dummy voltage VDUM of VST6 to the dummy word lines as shown in a graph 1130. The memory device may apply the dummy voltage VDUM of VST6 to the dummy word lines in the initialization section INIT. The memory device may maintain the dummy voltage VDUM of VST6 until the verifying operation ends. Similarly, the memory device may apply the dummy voltage VDUM of VST5 to dummy word lines as shown by a graph 1120 when a selected word line is located in the second stack STK2, and apply the dummy voltage VDUM of VST4 to dummy word lines as shown by a graph 1110 when a selected word line is located in the third stack STK3. Here, VST6 may be smaller than VST5 and VST4, and VST5 may be smaller than VST4. In some embodiments, VST4, VST5, and VST6 may have magnitudes equal to those of VST1, VST2, and VST3 in FIG. 10, respectively.

With reference to FIGS. 10 and 11, the case where the memory device is a three-stack structure has been described; however, the present disclosure is not necessarily limited thereto, and the memory device may be implemented in a multi-stack structure, such as a two-stack structure, a four-stack structure, an n-stack structure (wherein n is an integer greater than 4), etc. A memory device having an n-stack structure may determine n number of different dummy voltages VDUM, depending on the locations of selected word lines.

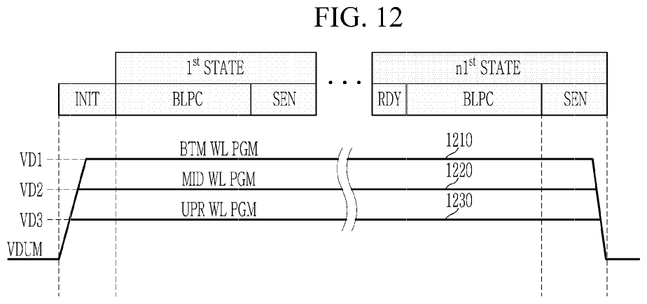

FIG. 12 is a drawing for explaining a configuration in which the memory device according to some embodiments applies dummy voltage.

Referring to FIG. 12, the memory device according to some embodiments may perform T2B programming. After performing a programming operation on a selected word line, the memory device may perform a verifying operation through an initialization section INIT, a first state section, and a second state section.

The memory device may determine a dummy voltage VDUM depending on the location of a selected word line in one stack, and apply the determined dummy voltage VDUM to dummy word lines. For example, when the selected word line is located in the bottom part BTM of the stack, the memory device may apply the dummy voltage VDUM of VD1 to dummy word lines as shown by a graph 1210. The memory device may apply the dummy voltage VDUM of VD1 to the dummy word lines in the initialization section INIT. The memory device may maintain the dummy voltage VDUM of VD1 until the verifying operation ends. Similarly, the memory device may apply the dummy voltage VDUM of VD2 to dummy word lines as shown by a graph 1220 when a selected word line is located in the middle part MID of the stack, and apply the dummy voltage VDUM of VD3 to dummy word lines as shown by a graph 1230 when a selected word line is located in the upper part UPR of the stack. Here, VD1 may be larger than VD2 and VD3, and VD2 may be larger than VD3.

The memory device may determine two reference points for distinguishing the upper part UPR, the middle part MID, and the bottom part BTM of the stack in advance. For example, the part of one stack from the bottom to a first reference point may be the bottom part BTM, the part of the stack from the first reference point to a second reference point may be the middle part MID, and the part of the stack from the second reference point to the top may be the upper part UPR.

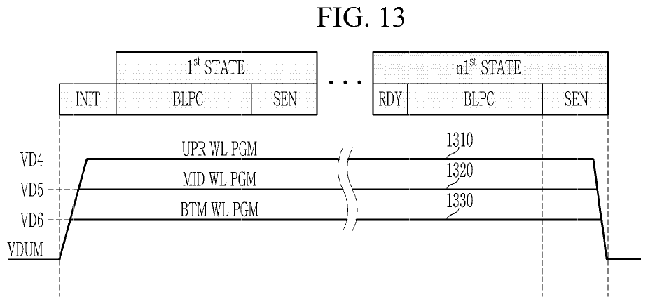

FIG. 13 is a drawing for explaining a configuration in which the memory device according to some embodiments applies dummy voltage.

Referring to FIG. 13, the memory device according to some embodiments may perform B2T programming. After performing a programming operation on a selected word line, the memory device may perform a verifying operation through an initialization section INIT, a first state section, and a second state section.

The memory device may determine a dummy voltage VDUM depending on the location of a selected word line in one stack, and apply the determined dummy voltage VDUM to dummy word lines. For example, when a selected word line is located in the upper part UPR of a stack, the memory device may apply the dummy voltage VDUM of VD4 to dummy word lines as shown by a graph 1310. The memory device may apply the dummy voltage VDUM of VD4 to the dummy word lines in the initialization section INIT. The memory device may maintain the dummy voltage VDUM of VD4 until the verifying operation ends. Similarly, the memory device may apply the dummy voltage VDUM of VD5 to dummy word lines as shown by a graph 1320 when a selected word line is located in the middle part MID of the stack, and apply the dummy voltage VDUM of VD6 to dummy word lines as shown by a graph 1330 when a selected word line is located in the bottom part BTM of the stack. Here, VD6 may be smaller than VD4 and VD5, and VD5 may be smaller than VD4. In some embodiments, VD4, VD5, and VD6 may have magnitudes equal to those of VD1, VD2, and VD3 in FIG. 12, respectively.

The memory device may determine two reference points for distinguishing the upper part UPR, the middle part MID, and the bottom part BTM of the stack in advance. For example, the part of one stack from the bottom to a first reference point may be the bottom part BTM, the part of the stack from the first reference point to a second reference point may be the middle part MID, and the part of the stack from the second reference point to the top may be the upper part UPR. With reference to FIGS. 12 and 13, the configurations in which one stack is divided into an upper part UPR, a middle part MID, and a bottom part BTM have been described; however, in some embodiments, one stack may be divided into an upper part UPR and a bottom part BTM, or the locations of selected word lines may be classified into smaller groups.

FIG. 14 is a drawing for explaining a configuration in which the memory device according to some embodiments applies dummy voltage.

Referring to FIG. 14, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation.

In the initialization section INIT, the memory device may apply a verification voltage VSEL to a selected word line. The memory device may apply the verification voltage of VP1 after applying the verification voltage VSEL of VR. In some embodiments, the memory device may immediately apply the verification voltage of VP1. The memory device may maintain the verification voltage of VP1 during the first state section.

In the initialization section INIT, the memory device may apply a dummy voltage VDUM to dummy word lines. In this case, the memory device may determine a dummy voltage VDUM depending on the location of a selected word line, and apply the determined dummy voltage VDUM to dummy word lines. The dummy word lines may include a word line adjacent to a string select line, word lines adjacent to a junction, and a word line adjacent to a ground select line. The memory device may determine a dummy voltage VDUM depending on which of the plurality of stacks STK1 to STK3 a selected word line is located in. The memory device may be a multi-stack structure including the first stack STK1, the second stack STK2, and the third stack STK3. In this case, the first stack STK1 and the second stack STK2 may be bonded, and the second stack STK2 and the third stack STK3 may be bonded. The second stack STK2 may be located on the first stack STK1, and the third stack STK3 may be located on the second stack STK2.

In some embodiments, the memory device may determine a dummy voltage VDUM in the initialization section INIT which is a word line setup section, and apply the determined dummy voltage VDUM to dummy word lines. For example, when a selected word line is located in the first stack STK1, the memory device may apply the dummy voltage VDUM of VST1_1 to the dummy word lines in the initialization section INIT as shown by a graph 1410. Similarly, the memory device may apply the dummy voltage VDUM of VST2_1 to dummy word lines as shown by a graph 1420 when a selected word line is located in the second stack STK2, and apply the dummy voltage VDUM of VST3_1 to dummy word lines as shown by a graph 1430 when a selected word line is located in the third stack STK3. Here, VST1_1 may be larger than VST2_1 and VST3_1, and VST2_1 may be larger than VST3_1. The memory device may maintain the determined dummy voltage VDUM during the first state section. In other words, the memory device may keep applying the determined dummy voltage VDUM in the bit line precharge sections BLPC1 and BLPC2 and the sensing section SEN of the first state section.

In the bit line precharge sections BLPC1 and BLPC2, the memory device may apply a bit line voltage VBL to the bit lines. The bit line precharge section BLPC1 may be an over precharge section in which the memory device applies the bit line voltage VBL of VOP, and the bit line precharge section BLPC2 may be a normal precharge section in which the memory device applies the bit line voltage VBL of VPR. VOP may be larger than VPR. The verifying period may include an over precharge section in order to offset the interference between a bit line to which the bit line voltage VBL is applied and the surrounding bit lines. In the readying section RDY of the second state section, the memory device may stop applying the bit line voltage VBL.

In some embodiments, the memory device may determine a dummy voltage VDUM in a section in which the level of the verification voltage VSEL changes, and apply the determined dummy voltage VDUM to dummy word lines. The section in which the level of the verification voltage VSEL changes may refer to the readying section RDY of the second state section. The memory device may determine to lower the dummy voltage VDUM. For example, when a selected word line is located in the first stack STK1, the memory device may lower the dummy voltage VDUM from VST1_1 to VST1_2 as shown by the graph 1410. The same description may be applied to when a selected word line is located in the second stack STK2 or the third stack STK3. In this case, the memory device may lower the dummy voltage VDUM from VST2_1 to VST2_2 when a selected word line is located in the second stack STK2 or may lower the dummy voltage VDUM from VST3_1 to VST3_2 when a selected word line is located in the third stack STK3 as shown by the graph 1420 or the graph 1430, respectively. The memory device may keep applying the lowered dummy voltage VDUM during the second state section, and may stop applying the dummy voltage VDUM and end the verifying operation, when the second state section ends.

In the readying section RDY, the memory device may lower the verification voltage VSEL. For example, the memory device may lower the verification voltage VSEL from VP1 to VR. In other words, in the initialization section INIT and the readying section RDY, the verification voltage VSEL may have the same voltage level. The memory device may apply the verification voltage VSEL of VP2 in the bit line precharge section BLPC1 of the second state section. VP2 may be smaller than VP1 and larger than VR. The memory device may maintain the verification voltage VSEL of VP2 during the bit line precharge sections BLPC1 and BLPC2 and the sensing section SEN.

As described above, the memory device may apply different dummy voltages VDUM depending on the locations of selected word lines, thereby capable of preventing cell distribution deterioration and improving the reliability of the memory device.

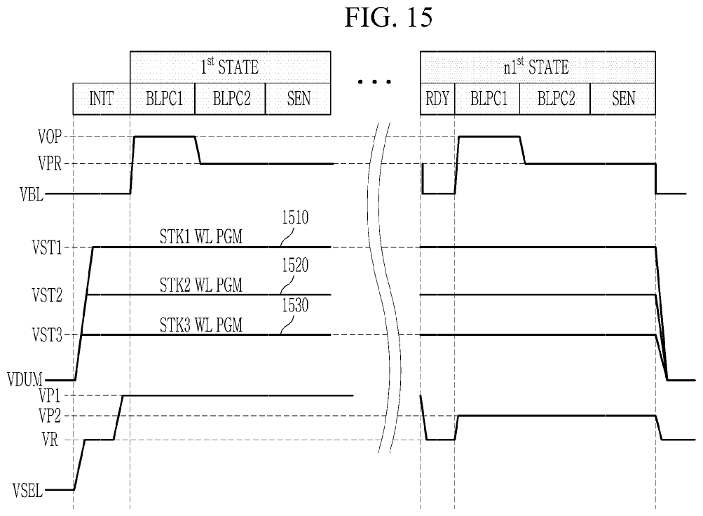

FIG. 15 is a drawing for explaining a configuration in which the memory device according to some embodiments applies dummy voltage.

Referring to FIG. 15, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation. In the initialization section INIT and the first state section, the memory device may operate as shown in FIG. 14. Accordingly, hereinafter for ease of explanation, the operation of the memory device in the second state section will be described.

In the readying section RDY of the second state section, the memory device may stop applying the bit line voltage VBL. Further, the memory device may keep applying the dummy voltage VDUM of the first state section. For example, when a selected word line is located in the first stack STK1, the memory device may maintain the dummy voltage VDUM at VST1 as shown by a graph 1510. The same description may be applied to when a selected word line is located in the second stack STK2 or the third stack STK3. In this case, the memory device may maintain the dummy voltage VDUM at VST2 when a selected word line is located in the second stack STK2 or may maintain the dummy voltage VDUM at VST3 when a selected word line is located in the third stack STK3 as shown by a graph 1520 or a graph 1530, respectively. The memory device may keep applying the dummy voltage VDUM during the second state section, and may stop applying the dummy voltage VDUM and end the verifying operation, when the second state section ends.

The memory device may apply the verification voltage VSEL of VR in the readying section RDY, and apply the verification voltage VSEL of VP2 in the bit line precharge section BLPC1 of the second state section. VP2 may be smaller than VP1 and larger than VR. The memory device may maintain the verification voltage VSEL of VP2 during the bit line precharge sections BLPC1 and BLPC2 and the sensing section SEN.

As described above, the memory device may apply different dummy voltages VDUM depending on the locations of selected word lines, thereby capable of preventing cell distribution deterioration and improving the reliability of the memory device.

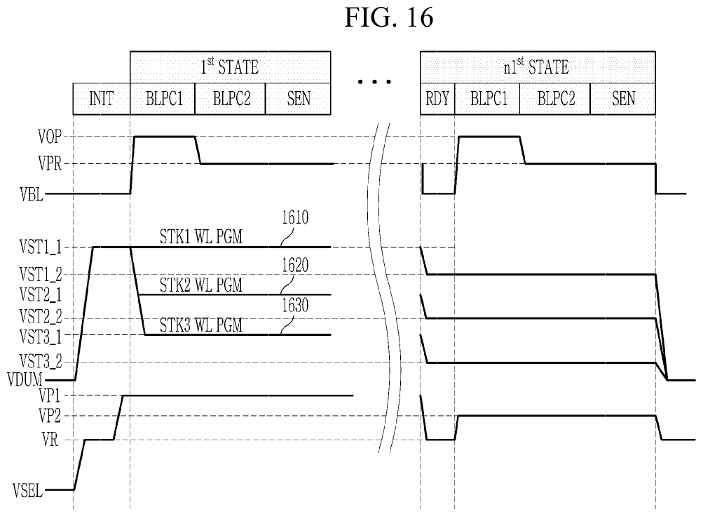

FIG. 16 is a drawing for explaining a configuration in which the memory device according to some embodiments applies dummy voltage.

Referring to FIG. 16, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation. A configuration in which the memory device applies the bit line voltage VBL and the verification voltage VSEL may be the same as that in FIG. 14. Further, a configuration in which the memory device applies the dummy voltage VDUM in the second state section may operate in the same way as in FIG. 14. Accordingly, hereinafter for ease of explanation, a configuration in which the memory device applies the dummy voltage VDUM in the initialization section INIT and the first state section will be described.

In the initialization section INIT, the memory device may apply the dummy voltage VDUM of VST1_1 to dummy word lines. In the bit line precharge section BLPC1, the memory device may determine a dummy voltage VDUM depending on the location of a selected word line, and apply the determined dummy voltage VDUM to dummy word lines. The dummy word lines may include a word line adjacent to a string select line, word lines adjacent to a junction, and a word line adjacent to a ground select line. The memory device may determine a dummy voltage VDUM depending on which of the plurality of stacks STK1 to STK3 a selected word line is located in. The memory device may be a multi-stack structure including the first stack STK1, the second stack STK2, and the third stack STK3. In this case, the first stack STK1 and the second stack STK2 may be bonded, and the second stack STK2 and the third stack STK3 may be bonded. The second stack STK2 may be located on the first stack STK1, and the third stack STK3 may be located on the second stack STK2.

In some embodiments, the memory device may determine a dummy voltage VDUM in the bit line precharge section BLPC1 which is a bit line setup section, and apply the determined dummy voltage VDUM to dummy word lines. For example, when a selected word line is located in the first stack STK1, the memory device may keep applying the dummy voltage VDUM of VST1_1 to the dummy word lines as shown by a graph 1610. Further, when a selected word line is located in the second stack STK2, the memory device may lower the dummy voltage VDUM from VST1_1 to VST2_1 as shown by a graph 1620. Similarly, when a selected word line is located in the third stack STK3, the memory device may lower the dummy voltage VDUM from VST1_1 to VST3_1 as shown by a graph 1630. Here, VST1_1 may be larger than VST2_1 and VST3_1, and VST2_1 may be larger than VST3_1. The memory device may maintain the determined dummy voltage VDUM during the first state section. In other words, the memory device may keep applying the determined dummy voltage VDUM in the bit line precharge section BLPC2 and the sensing section SEN of the first state section.

In some embodiments, the memory device may determine a dummy voltage VDUM in a section in which the level of the verification voltage VSEL changes, and apply the determined dummy voltage VDUM to dummy word lines. The section in which the level of the verification voltage VSEL changes may refer to the readying section RDY of the second state section. The memory device may determine to lower the dummy voltage VDUM. For example, when a selected word line is located in the first stack STK1, the memory device may lower the dummy voltage VDUM from VST1_1 to VST1_2 as shown by the graph 1610. The same description may be applied to when a selected word line is located in the second stack STK2 or the third stack STK3. In this case, the memory device may lower the dummy voltage VDUM from VST2_1 to VST2_2 when a selected word line is located in the second stack STK2 or may lower the dummy voltage VDUM from VST3_1 to VST3_2 when a selected word line is located in the third stack STK3 as shown by the graph 1620 or the graph 1630, respectively. The memory device may keep applying the lowered dummy voltage VDUM during the second state section, and stop applying the dummy voltage VDUM and end the verifying operation, when the second state section ends.

As described above, the memory device may apply different dummy voltages VDUM depending on the locations of selected word lines, thereby capable of preventing cell distribution deterioration and improving the reliability of the memory device.

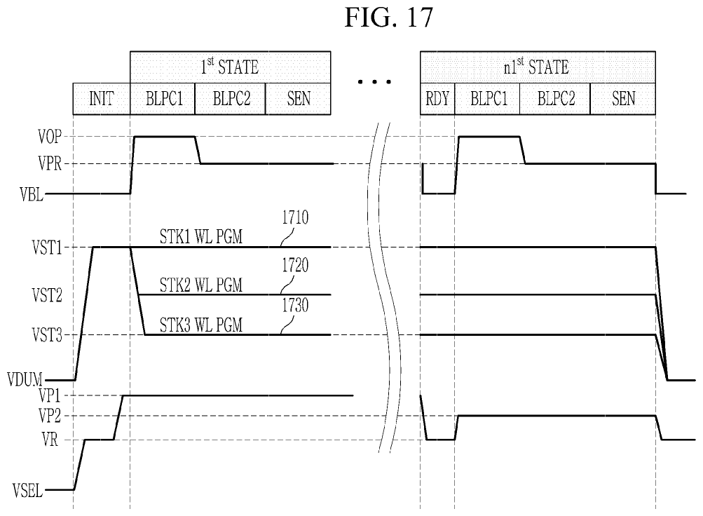

FIG. 17 is a drawing for explaining a configuration in which the memory device according to some embodiments applies dummy voltage.

Referring to FIG. 17, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation. In the initialization section INIT and the first state section, the memory device may operate as shown in FIG. 16. Further, a configuration in which the memory device applies the bit line voltage VBL and the verification voltage VSEL in the second state section may be the same as that in FIG. 16. Accordingly, hereinafter for ease of explanation, a configuration in which the memory device applies a dummy voltage VDUM in the second state section will be described.

In the second state section, the memory device may keep applying the dummy voltage VDUM of the first state section. For example, when a selected word line is located in the first stack STK1, the memory device may maintain the dummy voltage VDUM at VST1 as shown by a graph 1710. The same description may be applied to when a selected word line is located in the second stack STK2 or the third stack STK3.

In this case, the memory device may maintain the dummy voltage VDUM at VST2 when a selected word line is located in the second stack STK2 or may maintain the dummy voltage VDUM at VST3 when a selected word line is located in the third stack STK3 as shown by a graph 1720 or a graph 1730, respectively. The memory device may keep applying the dummy voltage VDUM during the second state section, and stop applying the dummy voltage VDUM and end the verifying operation, when the second state section ends.

As described above, the memory device may apply different dummy voltages VDUM depending on the locations of selected word lines, thereby capable of preventing cell distribution deterioration and improving the reliability of the memory device.

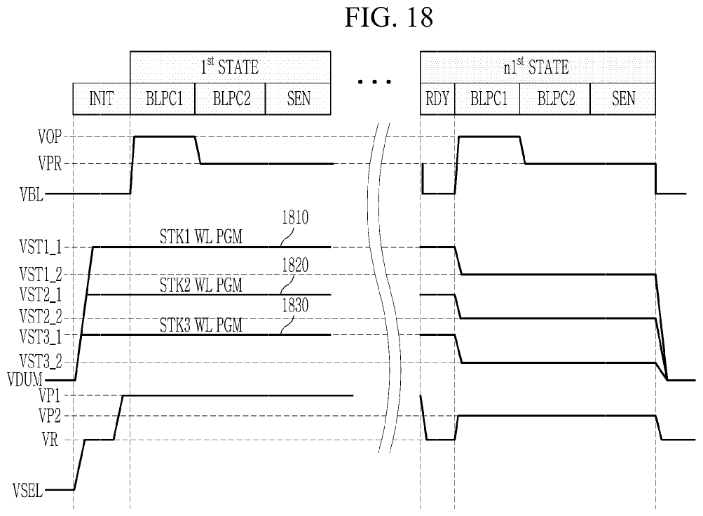

FIG. 18 is a drawing for explaining a configuration in which the memory device according to some embodiments applies dummy voltage.

Referring to FIG. 18, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation. In the initialization section INIT and the first state section, the memory device may operate as shown in FIG. 14. Further, a configuration in which the memory device applies the bit line voltage VBL and the verification voltage VSEL in the second state section may be the same as that in FIG. 14. Accordingly, hereinafter for ease of explanation, a configuration in which the memory device applies a dummy voltage VDUM in the second state section will be described.

In the readying section RDY of the second state section, the memory device may keep applying the dummy voltage VDUM of the first state section. For example, when a selected word line is located in the first stack STK1, the memory device may maintain the dummy voltage VDUM at VST1_1 as shown by a graph 1810. The same description may be applied to when a selected word line is located in the second stack STK2 or the third stack STK3. In this case, the memory device may maintain the dummy voltage VDUM at VST2_1 when a selected word line is located in the second stack STK2 or may maintain the dummy voltage VDUM at VST3_1 when a selected word line is located in the third stack STK3 as shown by a graph 1820 or a graph 1830, respectively.

In some embodiments, the memory device may determine a dummy voltage VDUM in the bit line precharge section BLPC1 which is a bit line setup section of the second state section, and apply the determined dummy voltage VDUM to dummy word lines. For example, the memory device may determine to lower the dummy voltage VDUM. When a selected word line is located in the first stack STK1, the memory device may lower the dummy voltage VDUM from VST1_1 to VST1_2. Similarly, when a selected word line is located in the second stack STK2, the memory device may lower the dummy voltage VDUM from VST2_1 to VST2_2, and when a selected word line is located in the third stack STK3, the memory device may lower the dummy voltage VDUM from VST3_1 to VST3_2. The memory device may keep applying the dummy voltage VDUM during the second state section, and stop applying the dummy voltage VDUM and end the verifying operation, when the second state section ends.

As described above, the memory device may apply different dummy voltages VDUM depending on the locations of selected word lines, thereby capable of preventing cell distribution deterioration and improving the reliability of the memory device.

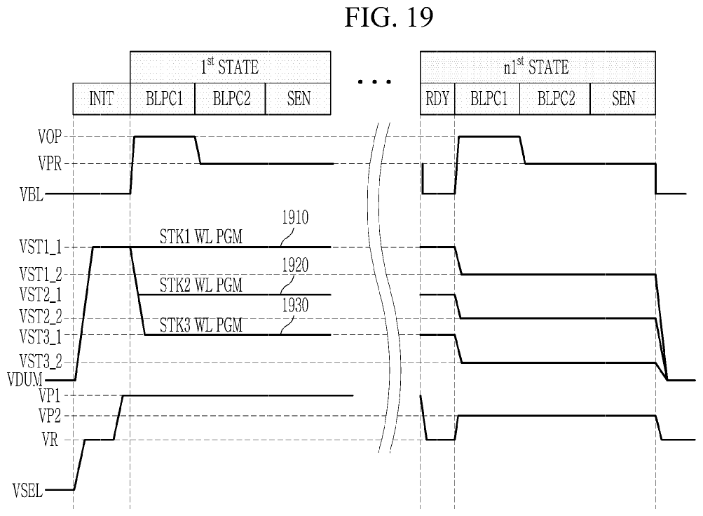

FIG. 19 is a drawing for explaining a configuration in which the memory device according to some embodiments applies dummy voltage.

Referring to FIG. 19, the memory device according to some embodiments may perform T2B programming. After performing a programming operation on a selected word line, the memory device may perform a verifying operation through an initialization section INIT in which the memory device performs word line setup, a first state section, and a second state section. The first state section may include bit line precharge sections BLPC1 and BLPC2 in which the memory device performs bit line setup, and a sensing section SEN after cutting off voltage to be applied to the bit lines. The second state section may include a readying section RDY in which the memory device initializes the previous verification and is readied for the subsequent verification, bit line precharge sections BLPC1 and BLPC2, and a sensing section SEN. Prior to the initialization section INIT, the memory device may have completed a programming operation. In the initialization section INIT and the first state section, the memory device may operate as shown in FIG. 16. Further, a configuration in which the memory device applies the bit line voltage VBL and the verification voltage VSEL in the second state section may be the same as that in FIG. 16. Accordingly, hereinafter for ease of explanation, a configuration in which the memory device applies a dummy voltage VDUM in the second state section will be described.

In the readying section RDY of the second state section, the memory device may keep applying the dummy voltage VDUM of the first state section. For example, when a selected word line is located in the first stack STK1, the memory device may maintain the dummy voltage VDUM at VST1_1 as shown by a graph 1910. The same description may be applied to when a selected word line is located in the second stack STK2 or the third stack STK3. In this case, the memory device may maintain the dummy voltage VDUM at VST2_1 when a selected word line is located in the second stack STK2 or may maintain the dummy voltage VDUM at VST3_1 when a selected word line is located in the third stack STK3 as shown by a graph 1920 or a graph 1930, respectively.

In some embodiments, the memory device may determine a dummy voltage VDUM in the bit line precharge section BLPC1 which is a bit line setup section of the second state section, and apply the determined dummy voltage VDUM to dummy word lines. For example, the memory device may determine to lower the dummy voltage VDUM. When a selected word line is located in the first stack STK1, the memory device may lower the dummy voltage VDUM from VST1_1 to VST1_2. Similarly, when a selected word line is located in the second stack STK2, the memory device may lower the dummy voltage VDUM from VST2_1 to VST2_2, and when a selected word line is located in the third stack STK3, the memory device may lower the dummy voltage VDUM from VST3_1 to VST3_2. The memory device may keep applying the dummy voltage VDUM during the second state section, and stop applying the dummy voltage VDUM and end the verifying operation, when the second state section ends.

As described above, the memory device may apply different dummy voltages VDUM depending on the locations of selected word lines, thereby capable of preventing cell distribution deterioration and improving the reliability of the memory device.

With reference to FIGS. 14 to 19, the cases where the memory device performs T2B programming have been described; however, the memory device may be implemented so as to perform B2T programming. In this case, the content about the dummy voltages described with reference to FIGS. 11 and 13 may be applied.

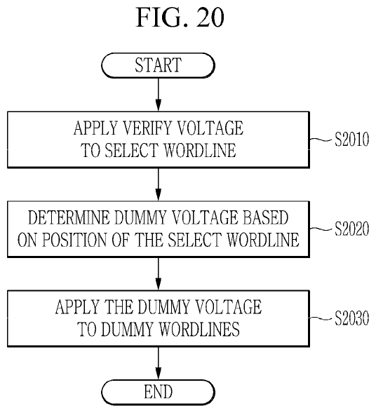

FIG. 20 is a flow chart of a memory device operating method according to some embodiments.

Referring to FIG. 20, the memory device according to some embodiments may perform a verifying operation after performing a programming operation on memory cells.

The memory device may apply a verification voltage to a selected word line corresponding to the memory cells having data programmed therein, for the verifying operation (S2010). The memory device may apply a verification pass voltage to nonselected word lines, for the verifying operation. At this time, the memory device may apply a dummy voltage to dummy word lines among the nonselected word lines. The dummy word lines may refer to word lines on which a programming operation is not performed.

For example, the dummy word lines may include word lines adjacent to a string select line, word lines adjacent to a ground select line, and word lines at junctions in the case where the memory device is a multi-stack structure. The junctions may refer to parts in the multi-stack structure in which a stack and another stack are in contact with each other.

The memory device may determine a dummy voltage on the basis of the location (i.e., position) of the selected word line (S2020). In some embodiments, the memory device may determine a dummy voltage on the basis of which stack the selected word line is located in. For example, the memory device may determine a first voltage as the dummy voltage when the selected word line is located in a lower stack. The memory device may determine a second voltage as the dummy voltage when the selected word line is located in an upper stack. In the case where the data has been programmed by T2B programming, the first voltage may be higher than the second voltage, and in the case where the data has been programmed by B2T programming, the first voltage may be lower than the second voltage.

In some embodiments, the memory device may determine a dummy voltage on the basis of the location of the selected word line in one stack. In the case of T2B programming, the memory device may apply a lower dummy voltage as the location of the selected word line is higher, and in the case of B2T programming, the memory device may apply a higher dummy voltage as the location of the selected word line is higher.

The memory device may apply the dummy voltage to the dummy word lines (S2030). The memory device may apply the dummy voltage in a word line setup section and/or a bit line setup section. The word line setup section may refer to a section in which a verification voltage is applied to the gate of the selected word line. The bit line setup section may refer to a section which follows the word line setup section and in which a bit line voltage is applied such that a current flows.

The memory device may perform verifying operations related to various states. In this case, after the memory device completes a verifying operation related to one state, during a verifying operation related to the next state, the memory device may apply the dummy voltage in a section in which the level of the verification voltage of the selected word line changes, or apply the dummy voltage in a section in which the bit line voltage is applied again after being initialized.

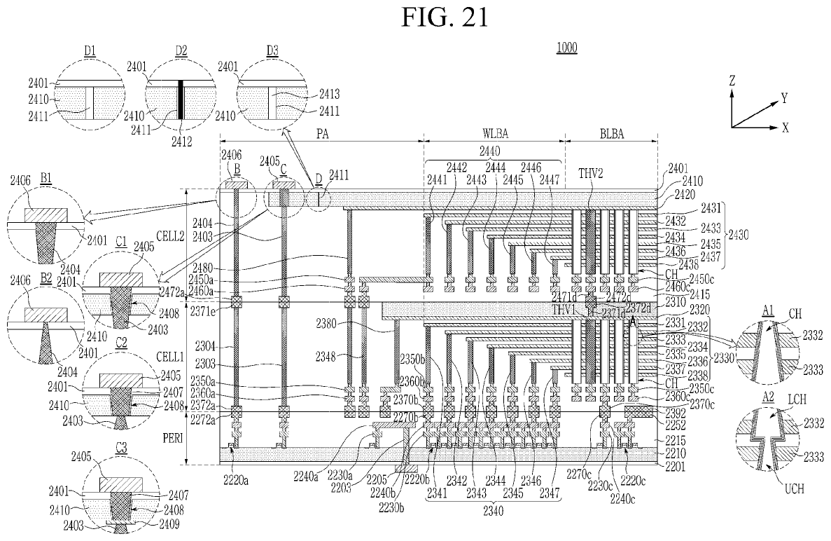

FIG. 21 is a drawing illustrating a memory device according to some embodiments.

Specifically, a memory device 1000 according to some embodiments of the present disclosure may perform the verifying operation described with reference to FIGS. 1 to 20. The memory device 1000 may include at least one upper chip including a cell region. For example, as shown in FIG. 21, the memory device 1000 may be implemented so as to include two upper chips. However, this is merely an example, and the number of upper chips is not limited thereto. When the memory device 1000 is implemented so as to include two upper chips, the memory device 1000 may be manufactured by manufacturing a first upper chip including a first cell region CELL1, a second upper chip including a second cell region CELL2, and a lower chip including a peripheral circuit region PERI and connecting the first upper chip, the second upper chip, and the lower chip by bonding. The first upper chip may be turned over and be connected to the lower chip by bonding, and the second upper chip may also be turned over and be connected to the first upper chip by bonding. In the following description, upper and lower directions refer to directions before the first upper chip and the second upper chip are turned over. In other words, the upper direction of the lower chip refers to a positive Z-axis direction, and the upper directions of the first and second upper chips refer to a negative Z-axis direction. However, this is merely an example, and the present disclosure is not limited thereto. Only one of the first upper chip and the second upper chip may be turned over and be connected by bonding.

Each of the peripheral circuit region PERI and the first and second cell regions CELL1 and CELL2 of the memory device 1000 may include an outer pad bonding area PA, a word line bonding area WLBA, and a bit line bonding area BLBA.

A peripheral circuit region PERI may include a first substrate 2210, and a plurality of circuit elements 2220a, 2220b, and 2220c that are formed on the first substrate 2210. On the plurality of circuit elements 2220a, 2220b, and 2220c, at least one interlayer insulating layer 2215 may be provided, and on the interlayer insulating layer 2215, a plurality of metal wiring lines may be provided so as to connect the plurality of circuit elements 2220a, 2220b, and 2220c. For example, the plurality of metal wiring lines may include first metal wiring lines 2230a, 2230b, and 2230c that are connected to the plurality of circuit elements 2220a, 2220b, and 2220c, respectively, and second metal wiring lines 2240a, 2240b, and 2240c that are formed on the first metal wiring lines 2230a, 2230b, and 2230c, respectively. The plurality of metal wiring lines may be made of various conductive materials. For example, the first metal wiring lines 2230a, 2230b, and 2230c may be formed of tungsten with relatively high electrical resistivity, and the second metal wiring lines 2240a, 2240b, and 2240c may be formed of copper with relatively low electrical resistivity.

In FIG. 21, only the first metal wiring lines 2230a, 2230b, and 2230c and the second metal wiring lines 2240a, 2240b, and 2240c are shown in the drawing and are described; however, the present disclosure is not limited thereto, and at least one metal wiring line may be further formed on the second metal wiring lines 2240a, 2240b, and 2240c. In this case, the second metal wiring lines 2240a, 2240b, and 2240c may be formed of aluminum. Further, at least some parts of the at least one metal wiring line that is formed on the second metal wiring lines 2240a, 2240b, and 2240c may be formed of copper with electrical resistivity lower than that of aluminum of the second metal wiring lines 2240a, 2240b, and 2240c.

The interlayer insulating layer 2215 may be disposed on the first substrate 2210, and may contain an insulating material such as silicon oxide, silicon nitride, etc.

The first and second cell regions CELL1 and CELL2 may provide at least one memory block. The first cell region CELL1 may include a second substrate 2310 and a common source line 2320. On the second substrate 2310, a plurality of word lines 2331 to 2338 (also referred to collectively as the word lines 2330) may be stacked along a direction perpendicular to the upper surface of the second substrate 2310 (the Z-axis direction). On and beneath the word lines 2330, string select lines SSL and ground select lines GSL may be disposed, and between the string select lines SSL and the ground select lines GSL, the plurality of word lines 2330 may be disposed. Similarly, the second cell region CELL2 may include a third substrate 2410 and a common source line 2420, and a plurality of word lines 2431 to 2438 (also referred to collectively as the word lines 2430) may be stacked along a direction perpendicular to the upper surface of the third substrate 2410 (the Z-axis direction). The second substrate 2310 and the third substrate 2410 may be made of various materials, and may be, for example, a silicon substrate, a silicon-germanium substrate, a germanium substrate, or a substrate having a monocrystalline epitaxial layer grown on a monocrystalline silicon substrate. In each of the first and second cell regions CELL1 and CELL2, a plurality of channel structures CH may be formed.

In some embodiments, as shown in part A1 in FIG. 21, a channel structure CH may be provided in the bit line bonding area BLBA, so as to extend through the word lines 2330, the string select lines, and the ground select line in a direction perpendicular to the upper surface of the second substrate 2310 (the Z-axis direction). The channel structure CH may include a data storage layer, a channel layer, a buried insulating layer, etc. The channel layer may be electrically connected to a first metal wiring line 2350c and a second metal wiring line 2360c in the bit line bonding area BLBA. For example, the second metal wiring line 2360c may be a bit line, and may be connected to the channel structure CH through the first metal wiring line 2350c. The bit line 2360c may extend along a first direction parallel with the upper surface of the second substrate 2310 (a Y-axis direction).

In some embodiments, as shown in part A2 in FIG. 21, a channel structure CH may include a lower channel LCH and an upper channel UCH connected to each other. For example, the channel structure CH may be formed through a process on the lower channel LCH and a process on the upper channel UCH. The lower channel LCH may extend in the direction perpendicular to the upper surface of the second substrate 2310 so as to pass through the common source line 2320 and the lower word lines 2331 and 2332. The lower channel LCH may include a data storage layer, a channel layer, a buried insulating layer, etc., and may be connected to the upper channel UCH. The upper channel UCH may pass through the upper word lines 2333 to 2338. The upper channel UCH may include a data storage layer, a channel layer, a buried insulating layer, etc., and the channel layer of the upper channel UCH may be electrically connected to the first metal wiring line 2350c and the second metal wiring line 2360c. As the length of a channel increases, it may get more difficult to form the channel such that the width is uniform, due to factors in the process. The memory device 1000 according to some embodiments of the present disclosure may have channels with improved width uniformity through lower channels LCH and upper channels UCH which are formed by sequential processes.

When a channel structure CH is formed so as to include a lower channel LCH and an upper channel UCH as shown in part A2 in FIG. 21, word lines located near the boundary between the lower channel LCH and the upper channel UCH may be dummy word lines. For example, the word line 2332 and the word line 2333 forming the boundary between the lower channel LCH and the upper channel UCH may be dummy word lines. In this case, data may not be stored in memory cells connected to the dummy word lines. Further, the number of pages that are constituted by memory cells connected to the dummy word lines may be smaller than the number of pages that are constituted by memory cells connected to general word lines. The level of voltage that is applied to the dummy word lines may be different from the level of voltage that is applied to the general word lines, and accordingly, it is possible to reduce the effect of the nonuniform channel width between the lower channel LCH and the upper channel UCH on the operation of the memory device.

Meanwhile, it is shown in part A2 in FIG. 21 that the number of lower word lines 2331 and 2332 passing through the lower channel LCH is smaller than the number of upper word lines 2333 to 2338 passing through the upper channel UCH. However, this is merely an example, and the present disclosure is not limited thereto. As another example, the number of lower word lines passing through the lower channel LCH may be equal to or larger than the number of upper word lines passing through the upper channel UCH. In addition, the structure and connection relationship of the channel structures CH disposed in the first cell region CELL1 described above may be applied to the channel structures CH disposed in the second cell region CELL2 in the same way.

In the bit line bonding area BLBA, a first through-hole electrode THV1 may be provided in the first cell region CELL1, and a second through-hole electrode THV2 may be provided in the second cell region CELL2. As shown in FIG. 21, the first through-hole electrode THV1 may pass through the common source line 2320 and the plurality of word lines 2330. However, this is merely an example, and the first through-hole electrode THV1 may further pass through the second substrate 2310. The first through-hole electrode THV1 may contain a conductive material. Alternatively, the first through-hole electrode THV1 may contain a conductive material surrounded by an insulating material. The second through-hole electrode THV2 may be provided in the same shape and structure as those of the first through-hole electrode THV1.

In some embodiments, the first through-hole electrode THV1 and the second through-hole electrode THV2 may be electrically connected through a first through-hole metal pattern 2372d and a second through-hole metal pattern 2472d. The first through-hole metal pattern 2372d may be formed in the lower part of the first upper chip including the first cell region CELL1, and the second through-hole metal pattern 2472d may be formed in the upper part of the second upper chip including the second cell region CELL2. The first through-hole electrode THV1 may be electrically connected to the first metal wiring line 2350c and the second metal wiring line 2360c. Between the first through-hole electrode THV1 and the first through-hole metal pattern 2372d, a lower via 2371d may be formed, and between the second through-hole electrode THV2 and the second through-hole metal pattern 2472d, an upper via 2471d may be formed. The first through-hole metal pattern 2372d and the second through-hole metal pattern 2472d may be connected by bonding.

Further, in the bit line bonding area BLBA, an upper metal pattern 2252 may be formed in the uppermost metal layer in the peripheral circuit region PERI, and an upper metal pattern 2392 may be formed in the uppermost metal layer in the first cell region CELL1, in the same shape as that of the upper metal pattern 2252. The upper metal pattern 2392 of the first cell region CELL1 and the upper metal pattern 2252 of the peripheral circuit region PERI may be electrically connected to each other by bonding. In the bit line bonding area BLBA, the bit line 2360c may be electrically connected to a page buffer included in the peripheral circuit region PERI. For example, some of the circuit elements 2220c in the peripheral circuit region PERI may provide a page buffer, and the bit line 2360c may be electrically connected to the circuit elements 2220c providing the page buffer, through an upper bonding metal 2370c of the first cell region CELL1 and an upper bonding metal 2270c of the peripheral circuit region PERI.

In addition, referring to FIG. 21, in the word line bonding area WLBA, the word lines 2330 of the first cell region CELL1 may extend along a second direction parallel with the upper surface of the second substrate 2310 (an X-axis direction), and may be connected to a plurality of cell contact plugs 2341 to 2347 (also referred to collectively as the cell contact plugs 2340). First metal wiring lines 2350b and second metal wiring lines 2360b may be sequentially connected to the upper parts of the cell contact plugs 2340 that are connected to the word lines 2330. The cell contact plugs 2340 may be connected to the peripheral circuit region PERI through upper bonding metals 2370b of the first cell region CELL1 and upper bonding metals 2270b of the peripheral circuit region PERI in the word line bonding area WLBA.

The cell contact plugs 2340 may be electrically connected to a row decoder included in the peripheral circuit region PERI. For example, some of the circuit elements 2220b in the peripheral circuit region PERI may provide a row decoder, and the cell contact plugs 2340 may be electrically connected to the circuit elements 2220b providing the row decoder through the upper bonding metals 2370b of the first cell region CELL1 and the upper bonding metals 2270b of the peripheral circuit region PERI. In some embodiments, the operating voltage of the circuit elements 2220b providing the row decoder may be different from the operating voltage of the circuit elements 2220c providing the page buffer. For example, the operating voltage of the circuit elements 2220c providing the page buffer may be larger than the operating voltage of the circuit elements 2220b providing the row decoder.

Similarly, in the word line bonding area WLBA, word lines 2430 in the second cell region CELL2 may extend along the second direction parallel with the upper surface of the third substrate 2410 (the X-axis direction) so as to be connected to a plurality of cell contact plugs 2441 to 2447 (also referred to collectively as the cell contact plugs 2440). The cell contact plugs 2440 may be connected the peripheral circuit region PERI through upper metal patterns of the second cell region CELL2, lower metal patterns and upper metal patterns of the first cell region CELL1, and the cell contact plug 2348.

In the word line bonding area WLBA, the upper bonding metals 2370b may be formed in the first cell region CELL1, and the upper bonding metals 2270b may be formed in the peripheral circuit region PERI. The upper bonding metals 2370b of the first cell region CELL1 and the upper bonding metals 2270b of the peripheral circuit region PERI may be electrically connected to each other by bonding. The upper bonding metals 2370b and the upper bonding metals 2270b may be formed of aluminum, copper, tungsten, etc.

In the outer pad bonding area PA, lower metal patterns 2371e may be formed in the lower part of the first cell region CELL1, and upper metal patterns 2472a may be formed in the upper part of the second cell region CELL2. The lower metal patterns 2371e of the first cell region CELL1 and the upper metal patterns 2472a of the second cell region CELL2 may be connected in the outer pad bonding area PA by bonding. Similarly, in the upper part of the first cell region CELL1, upper metal patterns 2372a may be formed, and in the upper part of the peripheral circuit region PERI, upper metal patterns 2272a may be formed. The upper metal patterns 2372a of the first cell region CELL1 and the upper metal patterns 2272a of the peripheral circuit region PERI may be connected by bonding.

In the outer pad bonding area PA, common source line contact plugs 2380 and 2480 may be disposed. The common source line contact plugs 2380 and 2480 may be formed of a conductive material such as a metal, a metal compound, polysilicon, etc. The common source line contact plug 2380 of the first cell region CELL1 may be electrically connected to the common source line 2320, and the common source line contact plug 2480 of the second cell region CELL2 may be electrically connected to the common source line 2420. On the common source line contact plug 2380 of the first cell region CELL1, a first metal wiring line 2350a and a second metal wiring line 2360a may be sequentially stacked, and on the common source line contact plug 2480 of the second cell region CELL2, a first metal wiring line 2450a and a second metal wiring line 2460a may be sequentially stacked.

In the outer pad bonding area PA, I/O pads 2205, 2405, and 2406 may be disposed. Referring to FIG. 21, on the lower surface of the first substrate 2210, a lower insulating layer 2201 may be formed so as to cover the lower surface of the first substrate 2210, and on the lower insulating layer 2201, the first I/O pad 2205 may be formed. The first I/O pad 2205 may be connected to at least one of the plurality of circuit elements 2220a disposed in the peripheral circuit region PERI, through a first I/O contact plug 2203, and may be separated from the first substrate 2210 by the lower insulating layer 2201. Further, between the first I/O contact plug 2203 and the first substrate 2210, a side insulating layer may be disposed so as to electrically separate the first I/O contact plug 2203 and the first substrate 2210.

On the third substrate 2410, an upper insulating layer 2401 may be formed so as to cover the upper surface of the third substrate 2410. On the upper insulating layer 2401, at least one of the second I/O pad 2405 or the third I/O pad 2406 may be disposed. The second I/O pad 2405 may be connected to at least one of the plurality of circuit elements 2220a, which is disposed in the peripheral circuit region PERI, through second I/O contact plugs 2403 and 2303, and the third I/O pad 2406 may be connected to at least one of the plurality of circuit elements 2220a, which is disposed in the peripheral circuit region PERI, through third I/O contact plugs 2404 and 2304.

In some embodiments, in the areas where the I/O contact plugs are disposed, the third substrate 2410 may not be disposed. For example, as shown in part B in FIG. 21, the third I/O contact plug 2404 may be separated from the third substrate 2410 in the direction parallel with the upper surface of the third substrate 2410 (e.g., the X-axis direction), and pass through an interlayer insulating layer 2415 of the second cell region CELL2, and be connected to the third I/O pad 2406. In this case, the third I/O contact plug 2404 may be formed by various processes.

As an example, as shown in part B1 in FIG. 21, the third I/O contact plug 2404 may be formed such that the third I/O contact plug extends in a third direction (the Z-axis direction) and the diameter thereof increases as it goes to the upper insulating layer 2401. In other words, while the diameter of the channel structure CH described with reference to the reference symbol “A1” decreases as it goes to the upper insulating layer 2401, the diameter of the third I/O contact plug 2404 may increase as it goes to the upper insulating layer 2401. For example, the third I/O contact plug 2404 may be formed after the second cell region CELL2 and the first cell region CELL1 are bonded by a bonding method.

Further, as an example, as shown in part B2 in FIG. 21, the third I/O contact plug 2404 may be formed such that the third I/O contact plug extends in the third direction (the Z-axis direction) and the diameter thereof decreases as it goes to the upper insulating layer 2401. In other words, similarly to the channel structure CH, the diameter of the third I/O contact plug 2404 may be formed such that the diameter thereof decreases as it goes to the upper insulating layer 2401. For example, the third I/O contact plug 2404 may be formed together with the cell contact plugs 2440 before bonding the second cell region CELL2 and the first cell region CELL1.

In another embodiment, the I/O contact plugs may be disposed so as to overlap the third substrate 2410. For example, as shown in part C in FIG. 21, the second I/O contact plug 2403 may be formed so as to pass through the interlayer insulating layer 2415 of the second cell region CELL2 in the third direction (the Z-axis direction) and be electrically connected to the second I/O pad 2405 through the third substrate 2410. In this case, the connection structure between the second I/O contact plug 2403 and the second I/O pad 2405 may be implemented in various ways.

As an example, as shown in part C1 in FIG. 21, an opening 2408 may be formed so as to pass through the third substrate 2410, and the second I/O contact plug 2403 may be connected directly to the second I/O pad 2405 through the opening 2408 formed in the third substrate 2410. In this case, as shown by the reference symbol “C1” in FIG. 21, the diameter of the second I/O contact plug 2403 may increase as it goes to the second I/O pad 2405. However, this is merely an example, and the diameter of the second I/O contact plug 2403 may decrease as it goes to the second I/O pad 2405.

As an example, as shown in part C2 in FIG. 21, an opening 2408 may be formed so as to pass through the third substrate 2410, and a contact 2407 may be formed in the opening 2408. One end part of the contact 2407 may be connected to the second I/O pad 2405, and the other end part may be connected to the second I/O contact plug 2403. Accordingly, the second I/O contact plug 2403 may be electrically connected to the second I/O pad 2405 through the contact 2407 formed in the opening 2408. In this case, as shown in part C2 in FIG. 21, the diameter of the contact 2407 may increase as it goes to the second I/O pad 2405, and the diameter of the second I/O contact plug 2403 may decrease as it goes to the second I/O pad 2405. For example, the third I/O contact plug 2403 may be formed together with the cell contact plugs 2440 before bonding the second cell region CELL2 and the first cell region CELL1, and the contact 2407 may be formed after bonding the second cell region CELL2 and the first cell region CELL1.

Also, as an example, a stopper 2409 may be further formed on the opening 2408 in the third substrate 2410 as shown in part C3 in FIG. 21. The stopper 2409 may be a metal wiring line formed in the same layer together with the common source line 2420. However, this is merely an example, and the stopper 2409 may be a metal wiring line formed in the same layer together with at least one of the word lines 2430. The second I/O contact plug 2403 may be electrically connected to the second I/O pad 2405 through the contact 2407 and the stopper 2409.

Meanwhile, like the second and third I/O contact plugs 2403 and 2404 of the second cell region CELL2, each of the second and third I/O contact plugs 2303 and 2304 of the first cell region CELL1 may be formed such that the diameter thereof decreases as it goes to the lower metal patterns 2371e, or increases as it goes to the lower metal patterns 2371e.

In some embodiments, a slit 2411 may be formed in the third substrate 2410. For example, the slit 2411 may be formed at an arbitrary location in the outer pad bonding area PA. As an example, as shown in part D in FIG. 21, the slit 2411 may be located between the second I/O pad 2405 and the cell contact plugs 2440 as seen in a plan view. However, this is merely an example, and the slit 2411 may be formed such that the second I/O pad 2405 is located between the slit 2411 and the cell contact plugs 2440 as seen in a plan view.

As an example, as shown in part D1 in FIG. 21, the slit 2411 may be formed so as to pass through the third substrate 2410. The slit 2411 can be used to prevent the substrate 2410 from cracking, for example, when the opening 2408 is formed. However, this is merely an example, and in some embodiments, the slit 2411 may be formed to a depth of about 60% to 70% of the thickness of the third substrate 2410.

Also, as an example, in the slit 2411, a conductive material 2412 may be formed as shown in part D2 in FIG. 21. The conductive material 2412 can be used to discharge leakage current occurring, for example, when driving circuit elements in the outer pad bonding area PA, to the outside (e.g., to a device external to the memory device 1000). In this case, the conductive material 2412 may be connected to an external ground line.

Also, as an example, in the slit 2411, an insulating material 2413 may be formed as shown in part D3 in FIG. 21. The insulating material 2413 may be formed, for example, in order to electrically separate the second I/O pad 2405 and the second I/O contact plug 2403 disposed in the outer pad bonding area PA from the word line bonding area WLBA. By forming the insulating material 2413 in the slit 2411, it is possible to prevent the voltage which is supplied through the second I/O pad 2405 from affecting the metal layer of the word line bonding area WLBA disposed on the upper surface of the third substrate 2410.

In some embodiments, the first to third I/O pads 2205, 2405, and 2406 may be selectively formed. For example, the memory device 1000 may be implemented so as to include only the first I/O pad 2205 that is disposed on the first substrate 2210, or to include only the second I/O pad 2405 that is disposed on the third substrate 2410, or to include only the third I/O pad 2406 that is disposed on the upper insulating layer 2401.

In some embodiments, at least one of the second substrate 2310 of the first cell region CELL1 and the third substrate 2410 of the second cell region CELL2 may be used as a sacrificial substrate, and may be wholly or partially removed before or after the bonding process. After the substrate is removed, additional layers may be stacked. For example, the second substrate 2310 of the first cell region CELL1 may be removed before or after bonding the peripheral circuit region PERI and the first cell region CELL1, and an insulating layer for covering the upper surface of the common source line 2320 or a conductive layer for connection may be formed. Similarly, the third substrate 2410 of the second cell region CELL2 may be removed before or after bonding the first cell region CELL1 and the second cell region CELL2, and the upper insulating layer 2401 for covering the upper surface of the common source line 2420 or a conductive layer for connection may be formed.

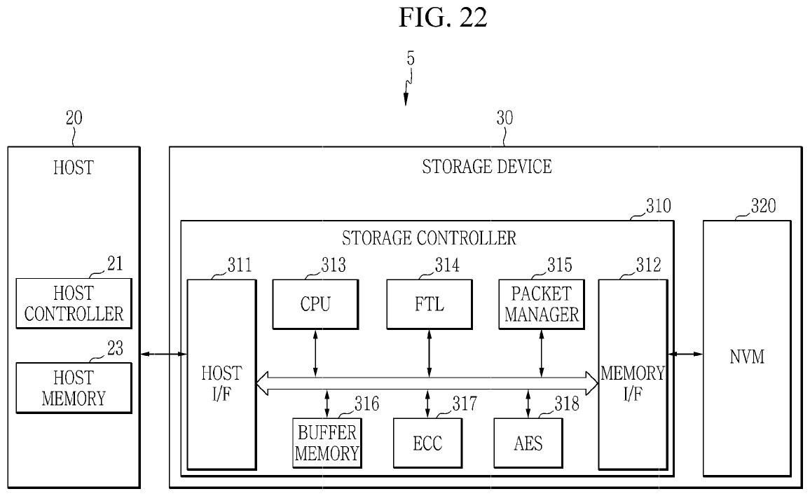

FIG. 22 is a schematic block diagram of a computing system according to some embodiments.

Referring to FIG. 22, a computing system 5 may be implemented as a personal computer (PC), a data server, a laptop computer, or a portable device. The portable device may be implemented as a mobile phone, a smart phone, a tablet PC, a wearable device, a personal digital assistant (PDA), an enterprise digital assistant (EDA), a digital still camera, a digital video camera, a portable multimedia player (PMP), a personal navigation device or portable navigation device (PND), a handheld game console, or an e-book. Also, the computing system 5 may be implemented as a system-on-chip (SOC).

The computing system 5 may include a host 20 and a storage device 30. The host 20 may perform communication with the storage device 30 through various interfaces. The host 20 may request, from the storage device 30, a data processing operation, such as a data read operation, a data programming (writing) operation, a data erasing operation, etc. For example, the host 20 may be a CPU, a GPU, a microprocessor, an AP, etc.

The host 20 may include a host controller 21 and a host memory 23. The host memory 23 malfunction as a buffer memory for temporarily storing data to be transmitted to the storage device 30 or data received from the storage device 30.

The storage device 30 may include a storage controller 310 and a non-volatile memory (NVM) 320. The storage device 30 may include storage media for storing data in response to requests from the host 20. For example, the storage device 30 may be implemented in various types such as an SSD, an eMMC, a UFS, a CF, an SD, a Micro-SD, a Mini-SD, an xD, a memory stick, etc.

When the storage device 30 is an SSD, the storage device 30 may be a device complying with the non-volatile memory express (NVMe) standards. When the storage device 30 is an embedded memory or an external memory, the storage device 30 may be a device complying with the UFS standards or the eMMC standards. The host 20 and the storage device 30 may generate packets according to the standard protocols adopted for them, and transmit the packets.

When the non-volatile memory 320 of the storage device 30 includes a flash memory, the flash memory may include a 2D NAND memory array or a 3D NAND memory array. As another example, the storage device 30 may include various other types of non-volatile memories. For example, as the storage device 30, various types of memories, such as an MRAM, an STT-RAM, a CBRAM, an FeRAM, a PRAM, a RRAM, etc., may be applied.

In some embodiments, the host controller 21 and the host memory 23 may be implemented as separate semiconductor chips. Alternatively, in some embodiments, the host controller 21 and the host memory 23 may be integrated in the same semiconductor chip. As an example, the host controller 21 may be one of a number of modules that are provided in an AP, and such an AP may be implemented as a SOC. Also, the host memory 23 may be an embedded memory that is provided in an AP, or a non-volatile memory or a memory module that is disposed outside an AP.

The host controller 21 may manage the operation of storing data of a buffer area (for example, program data) in the non-volatile memory 320 or storing data of the non-volatile memory 320 (for example, read data) in the buffer area. The content described about the memory device with reference to FIGS. 1 to 21 may be applied to the non-volatile memory 320 in the same way. In other words, the non-volatile memory 320 may determine a dummy voltage depending on the location of a selected word line corresponding to data cells (e.g., memory cells) having program data written therein, and may apply the determined dummy voltage to dummy word lines. In some embodiments, a CPU 313 of the storage controller 310 may determine the dummy voltage of the non-volatile memory 320.

The storage controller 310 may include a host interface 311, a memory interface 312, and a CPU 313. In addition, the storage controller 310 may further include a flash translation layer (FTL) 314, a packet manager 315, a buffer memory 316, an error correction code (ECC) engine 317, and an advanced encryption standard (AES) engine 318.

The storage controller 310 may further include a working memory in which the FTL 314 is loaded, and the CPU 313 may execute the FTL 314, whereby a data programming operation and a data read operation on the non-volatile memory 320 can be controlled.

The host interface 311 may transmit and receive packets to and from the host 20. A packet which is transmitted from the host 20 to the host interface 311 may include commands or data to be programmed in the non-volatile memory 320, etc., and a package which is transmitted from the host interface 311 to the host 20 may include responses to commands, or data read from the non-volatile memory 320, etc.

The memory interface 312 may transmit data to be programmed in the non-volatile memory 320, to the non-volatile memory 320, or may receive data read from the non-volatile memory 320. The memory interface 312 may be implemented so as to comply with a standard such as Toggle or ONFI.

The FTL 314 may perform various functions such as address mapping, wear-leveling, garbage collection, etc. An address mapping operation is an operation of converting a logical address received from the host 20 integrated on a physical address to be used to actually store data in the non-volatile memory 320. Wear-leveling is a technique for preventing excessive deterioration of specific memory blocks by making the blocks in the non-volatile memory 320 evenly used, and may be realized, for example, through a firmware technique of balancing the erase counts of the physical blocks. Garbage collection is a technique for securing available capacity in the non-volatile memory 320 by copying valid data in a block into a new block and erasing the corresponding block.

The packet manager 315 may generate a packet according to the protocol of the interface prearranged with the host 20, or may parse various information from a packet received from the host 20. Also, the buffer memory 316 may temporarily store data to be programmed in the non-volatile memory 320 or data read from the non-volatile memory 320. The buffer memory 316 may be provided in the storage controller 310, but may be disposed outside the storage controller 310.

The ECC engine 317 may perform an error detection and correction function on read data that is read from the non-volatile memory 320. More specifically, the ECC engine 317 may generate parity bits with respect to write data to be written in the non-volatile memory 320, and the generated parity bits may be stored in the non-volatile memory 320, together with program data. When reading data from the non-volatile memory 320, the ECC engine 317 may correct errors in the read data, using parity bits read from the non-volatile memory 320 together with the read data, and may output the corrected read data.

The AES engine 318 may perform at least one of an encryption operation or a decryption operation on data which is input to the storage controller 310, using a symmetric-key algorithm.

In some embodiments, each of the constituent elements described with reference to FIGS. 1 to 22, or a combination of two or more constituent elements may be implemented as a digital circuit, a programmable or non-programmable logic device or array, application specific integrated circuit (ASIC), etc.

While the present disclosure has been described in connection with example embodiments thereof, it is to be understood that the present disclosure is not limited to the disclosed example embodiments. On the contrary, it is intended to cover various modifications and equivalent arrangements included within the scope of the appended claims.

What is claimed is:

1. A memory device comprising:
a memory cell that is configured to have data stored therein; and
a control logic that is configured to determine a dummy voltage based on a location of a selected word line electrically connected to the memory cell, and is configured to apply the dummy voltage to dummy word lines,
wherein first and second ones of the dummy word lines are adjacent to opposing ends in a vertical direction of a memory NAND string including the memory cell, respectively.

2. The memory device of claim 1, wherein the memory NAND string is on a substrate and comprises a multi-stack structure that includes a first stack and a second stack on the first stack,
wherein the first stack is between the second stack and the substrate, and
wherein third and fourth ones of the dummy word lines are adjacent to a junction between the first stack and the second stack.

3. The memory device of claim 2, wherein the control logic is configured to determine the dummy voltage based on the location of the selected word line in one of the first and second stacks.

4. The memory device of claim 2, wherein the control logic is configured to determine the dummy voltage based on which one of the first and second stacks the selected word line is located in.

5. The memory device of claim 4, wherein, in a case of Top-to-Bottom (T2B) programming, the control logic is configured to apply the dummy voltage having a first voltage when the selected word line is located in the first stack, and is configured to apply the dummy voltage having a second voltage lower than the first voltage when the selected word line is located in the second stack.

6. The memory device of claim 4, wherein, in a case of Bottom-to-Top (B2T) programming, the control logic is configured to apply the dummy voltage having a first voltage when the selected word line is located in the first stack, and is configured to apply the dummy voltage having a second voltage higher than the first voltage when the selected word line is located in the second stack.

7. The memory device of claim 1, wherein the memory NAND string is on a substrate, and
wherein, when the location of the selected word line is higher than a first height in the memory NAND string relative to the substrate, the control logic is configured to apply the dummy voltage having a lower voltage than a voltage applied by the control logic when the location of the selected word line is lower than the first height in the memory NAND string, in a case of Top-to-Bottom (T2B) programming.

8. The memory device of claim 7, wherein the control logic is configured to:
determine a first reference point in the memory NAND string and a second reference point higher than the first reference point in the memory NAND string relative to the substrate;
determine the selected word line is a lower word line when the location of the selected word line is lower than the first reference point, determine the selected word line is a middle word line when the location of the selected word line is between the first reference point and the second reference point, and determine the selected word line is an upper word line when the location of the selected word line is higher than the second reference point; and
apply the dummy voltage having a first voltage when the selected word line is the lower word line, apply the dummy voltage having a second voltage lower than the first voltage when the selected word line is the middle word line, and apply the dummy voltage having a third voltage lower than the second voltage when the selected word line is the upper word line.

9. The memory device of claim 1, wherein the memory NAND string is on a substrate, and
wherein, when the location of the selected word line is lower than a first height in the memory NAND string relative to the substrate, the control logic is configured to apply the dummy voltage having a lower voltage than a voltage applied by the control logic when the location of the selected word line is higher than the first height in the memory NAND string, in a case of Bottom-to-Top (B2T) programming.

10. The memory device of claim 9, wherein the control logic is configured to:
determine a first reference point in the memory NAND string and a second reference point higher than the first reference point in the memory NAND string relative to the substrate;
determine the selected word line is a lower word line when the location of the selected word line is lower than the first reference point, determine the selected word line is a middle word line when the location of the selected word line is between the first reference point and the second reference point, and determine the selected word line is an upper word line when the location of the selected word line is higher than the second reference point; and
apply the dummy voltage having a first voltage when the selected word line is the lower word line, apply the dummy voltage having a second voltage higher than the first voltage when the selected word line is the middle word line, and apply the dummy voltage having a third voltage higher than the second voltage when the selected word line is the upper word line.

11. The memory device of claim 1, wherein the control logic is configured to determine the dummy voltage based on a program/erase cycle (P/E cycle) or a temperature of the memory cell.

12. The memory device of claim 11, wherein the control logic is configured to apply the dummy voltage having a first voltage when the P/E cycle of the memory cell is higher than a first reference value, and is configured to apply the dummy voltage having a second voltage lower than the first voltage when the P/E cycle of the memory cell is lower than the first reference value.

13. The memory device of claim 11, wherein the control logic is configured to apply the dummy voltage having a first voltage when the temperature of the memory cell is higher than a first reference value, and is configured to apply the dummy voltage having a second voltage higher than the first voltage when the temperature of the memory cell is lower than the first reference value.

14. A memory device comprising:
a memory cell that is configured to have data stored therein; and
a control logic that is configured to:
apply a verification voltage to a selected word line electrically connected to the memory cell during a verifying period for verifying the memory cell;
apply a dummy voltage to dummy word lines during the verifying period; and
apply a verification pass voltage to unselected word lines other than the dummy word lines during the verifying period.

15. The memory device of claim 14, wherein the control logic is configured to apply the dummy voltage in a word line setup section of the verifying period.

16. The memory device of claim 14, wherein the control logic is configured to apply the dummy voltage in a bit line setup section of the verifying period.

17. The memory device of claim 14, wherein the verifying period comprises a first state verification section for verifying a first state of the memory cell, and
wherein, in a second state verification section following the first state verification section, the control logic is configured to lower the dummy voltage while lowering the verification voltage in order to verify a second state of the memory cell.

18. A memory device operating method comprising:
applying a verification voltage to a selected word line electrically connected to a memory cell having data stored therein;
determining a dummy voltage based on a location of the selected word line; and
applying the dummy voltage to dummy word lines located at an upper end and a lower end of a memory NAND string including the memory cell, respectively.

19. The memory device operating method of claim 18, wherein the memory NAND string is on a substrate, and
wherein determining the dummy voltage comprises:
determining the dummy voltage as a first voltage when the location of the selected word line is higher than a first height in the memory NAND string relative to the substrate and determining the dummy voltage as a second voltage higher than the first voltage when the location of the selected word line is lower than the first height in the memory NAND string, in a case where the data has been programmed by Top-to-Bottom (T2B) programming; and
determining the dummy voltage as a third voltage when the location of the selected word line is higher than the first height in the memory NAND string and determining the dummy voltage as a fourth voltage lower than the third voltage when the location of the selected word line is lower than the first height in the memory NAND string, in a case where the data has been programmed by Bottom-to-Top (B2T) programming.

20. The memory device operating method of claim 18, wherein applying the dummy voltage includes applying the dummy voltage in a word line setup section or a bit line setup section following the word line setup section.
